(19) United States
(12) Patent Application Publication
(10) Pub. No.: US 2026/0323900 A1
(43) Pub. Date: Oct. 15, 2026

(54) MEMORY DEVICE BASED ON CFET STRUCTURE AND METHOD FOR MANUFACTURING THE SAME

(71) Applicants: TAIWAN SEMICONDUCTOR MANUFACTURING COMPANY, LTD., Hsinchu (TW); NATIONAL TAIWAN UNIVERSITY, TAIPEI (TW)

(72) Inventors: Ching-Wang YAO, New Taipei City (TW); Fang-Yu CHANG, Hualien City (TW); Hsin-Cheng LIN, Taipei City (TW); Chee-Wee LIU, Taipei City (TW)

(73) Assignees: TAIWAN SEMICONDUCTOR MANUFACTURING COMPANY, LTD., Hsinchu (TW); NATIONAL TAIWAN UNIVERSITY, TAIPEI (TW)

(21) Appl. No.: 19/175,430

(22) Filed: Apr. 10, 2025

(51) Int. Cl. H10B 10/00; H01L 23/522; H01L 23/528; H10D 30/00; H10D 30/01; H10D 62/10

(52) U.S. Cl. CPC H10B 10/12; H10W 20/42; H10W 20/435; H10D 30/019; H10D 30/502; H10D 62/121

(57) ABSTRACT

A device includes a first transistor, a second transistor, a third transistor, and a fourth transistor. The first transistor and the second transistor are disposed in a first semiconductor level. The first transistor includes a first active region extending in a first direction, and the first transistor and the second transistor are arranged in a second direction different from the first direction. The third transistor is disposed in the first semiconductor level, between the first transistor and the second transistor, and is misaligned with the first transistor in the second direction. The third transistor is electrically connected to the first transistor and the second transistor. The fourth transistor is disposed in a second semiconductor level and over the first transistor to form a complementary field effect transistor with the first transistor. The second semiconductor level is over the first semiconductor level.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of part of a memory device, in accordance with some embodiments of the present disclosure.

FIG. 2 is a perspective view of the memory device of FIG. 1, in accordance with some embodiments of the present disclosure.

FIG. 3A is a layout diagram of backside conductive lines and a first semiconductor level (or a bottom tier) of the memory device of FIG. 1.

FIG. 3B is a layout diagram of a second semiconductor level (or a top tier) of the memory device of FIG. 1.

FIG. 3C is a layout diagram of front-side conductive lines of the memory device of FIG. 1.

FIG. 4 is a graph illustrating input/output voltages with time of the memory devices with/without the third pass transistor.

FIG. 5A is a schematic diagram of part of the memory device of FIG. 1 and an inverter chain, in accordance with some embodiments of the present disclosure.

FIGS. 5B and 5C are graphs illustrating input/output/result voltages with time of the memory device.

FIG. 6 is a schematic diagram of part of a memory device, in accordance with some embodiments of the present disclosure.

FIG. 7 is a perspective view of the memory device of FIG. 6, in accordance with some embodiments of the present disclosure.

FIG. 8A is a layout diagram of backside conductive lines and a first semiconductor level (or a bottom tier) of the memory device of FIG. 6.

FIG. 8B is a layout diagram of a second semiconductor level (or a top tier) of the memory device of FIG. 6.

FIG. 8C is a layout diagram of front-side conductive lines of the memory device of FIG. 6.

FIGS. 9A-9D are graphs illustrating computing signals of the memory device, in accordance with some embodiments of the present disclosure.

FIG. 10 illustrates a flowchart of a method for forming a memory cell configured in a CFET structure, in accordance with some embodiments of the present disclosure.

FIGS. 11-16 are perspective view and cross-sectional views for forming a memory device configured in a CFET structure, in accordance with some embodiments of the present disclosure.

FIG. 17A is a cross-sectional view of the memory device along a line I-I in FIGS. 3A-3C, in accordance with some embodiments of the present disclosure.

FIG. 17B is a cross-sectional view of the memory device along a line II-II in FIGS. 3A-3C, in accordance with some embodiments of the present disclosure.

FIG. 17C is a cross-sectional view of the memory device along a line III-III in FIGS. 3A-3C, in accordance with some embodiments of the present disclosure.

FIG. 18A is a cross-sectional view of the memory device along a line IV-IV in FIGS. 8A-8C, in accordance with some embodiments of the present disclosure.

FIG. 18B is a cross-sectional view of the memory device along a line V-V in FIGS. 8A-8C, in accordance with some embodiments of the present disclosure.

FIG. 18C is a cross-sectional view of the memory device along a line VI-VI in FIGS. 8A-8C, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

As used herein, the term “conductive” refers to an electrically conductive structure, layer, and/or region. As used herein, source/drain region(s) may refer to a source or a drain, individually or collectively dependent upon the context.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to memory devices and methods of forming the memory devices. More particularly, some embodiments of the present disclosure are related to memory devices which include nine transistors (9T) to improve output voltage degradation issues or include ten transistors (10T) to increase output throughput of digital computing without increasing the layout area of the memory devices.

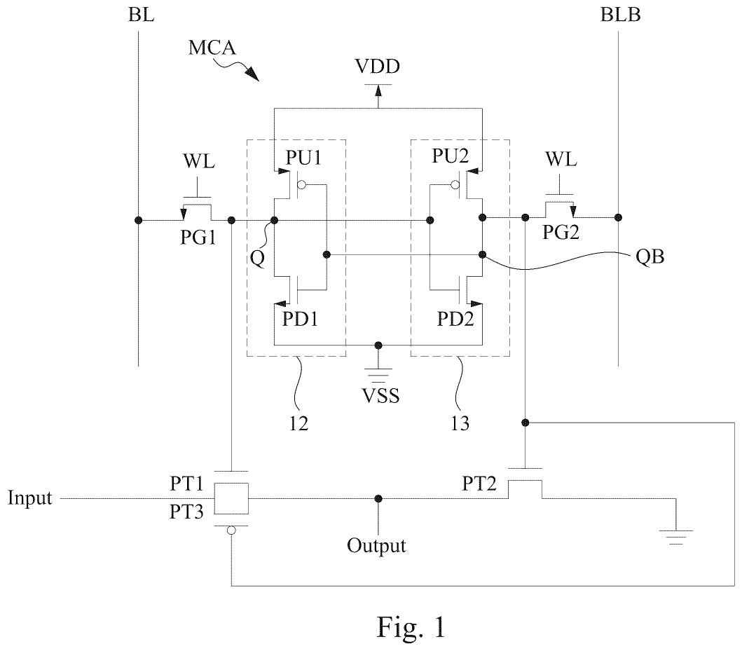

FIG. 1 is a schematic diagram of part of a memory device 10A, in accordance with some embodiments of the present disclosure. For illustration, a memory cell MCA in the memory device 10A is coupled to bit lines BL and BLB. In some embodiments, the memory cell MCA includes an inverter 12 and an inverter 13. The inverter 12 and the inverter 13 are cross-coupled. Effectively, the inverter 12 and the inverter 13 operate as a data latch. For illustration, an output node of the inverter 12 and an input node of the inverter 13 are connected together at a node Q shown in FIG. 1. An input node of the inverter 12 and an output node of the inverter 13 are connected together at a node QB shown in FIG. 1.

For illustration of operation, the data latch, including the inverter 12 and the inverter 13, is able to store a bit of data at the node Q. For illustration, a voltage level on the node Q is able to be configured at different voltage levels. The voltage level of the node Q represents logic “1” or logic “0” corresponding to logic data stored in the memory cell MCA. The node QB has a logical level opposite to that of the node Q. For convenience of illustration hereinafter, logic “0” indicates a low level, and logic “1” indicates a high level. The indications are given for illustrative purposes. Various indications are within the contemplated scope of the present disclosure.

In some embodiments, the memory cell MCA illustrated in FIG. 1 is a static random-access memory (SRAM) cell, including, for illustration, nine transistors (9T) PU1-PU2, PD1-PD2, PG1-PG2, and PT1-PT3. The pull up transistor PU1 and the pull down transistor PD1 are configured and operate as the inverter 12. The pull up transistor PU2 and the pull down transistor PD2 are configured and operate the inverter 13. In some embodiments, the pull down transistors PD1-PD2, the pass gate transistors PG1-PG2, and the pass transistors PT1-PT2 are N-type transistors (first electrical conductivity type), and the pull up transistors PU1-PU2 and the pass transistor PT3 are P-type transistors (second electrical conductivity type), or vice versa. It is noted that the transistors PU1-PU2, PD1-PD2, PG1-PG2, and PT1-PT3 may be FinFETs, GAA FETs, TreeFETs, or other suitable transistors.

In some embodiments, the transistor PG1 is configured as a first pass gate transistor, and the transistor PG2 is configured as a second pass gate transistor. For illustration, gate terminals of the transistor PG1 and the transistor PG2 are coupled to a word line WL and controlled by a word line signal. The output node of the inverter 12 and the input node of the inverter 13, i.e., the node Q, are coupled through the transistor PG1 to the bit line BL. The input node of the inverter 12 and the output node of the inverter 13, i.e., the node QB, are coupled through the transistor PG2 to the complementary bit line BLB.

The pass transistors PT1-PT3 are used for digital compute-in-memory (DCIM) applications. The gate terminal of the pass transistor PT1 is coupled to the node Q, and the gate terminals of the pass transistors PT2 and PT3 are coupled to the node QB. The input terminal of the memory device 10A is coupled through the pass transistors PT1 and PT3 to the output terminal of the memory device 10A, which is coupled through the pass transistor PT2 to the ground (e.g., the supply voltage VSS in this case).

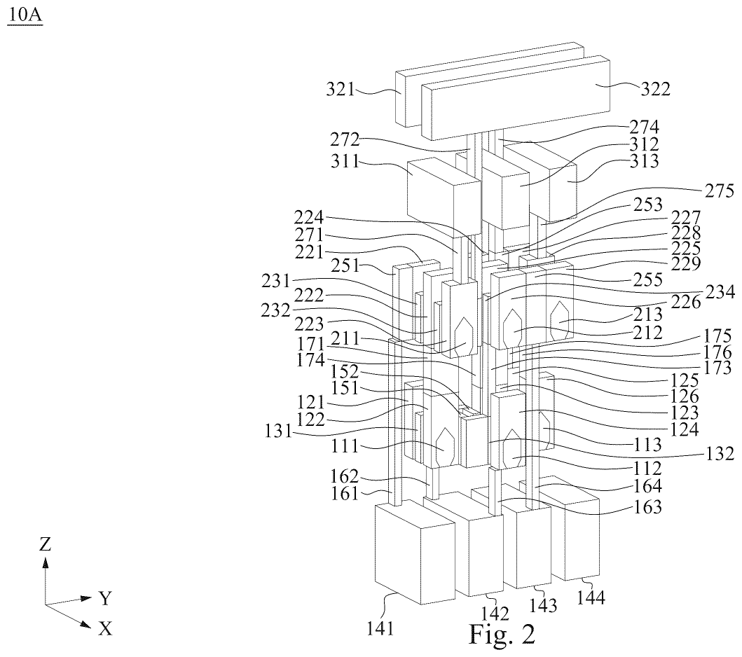

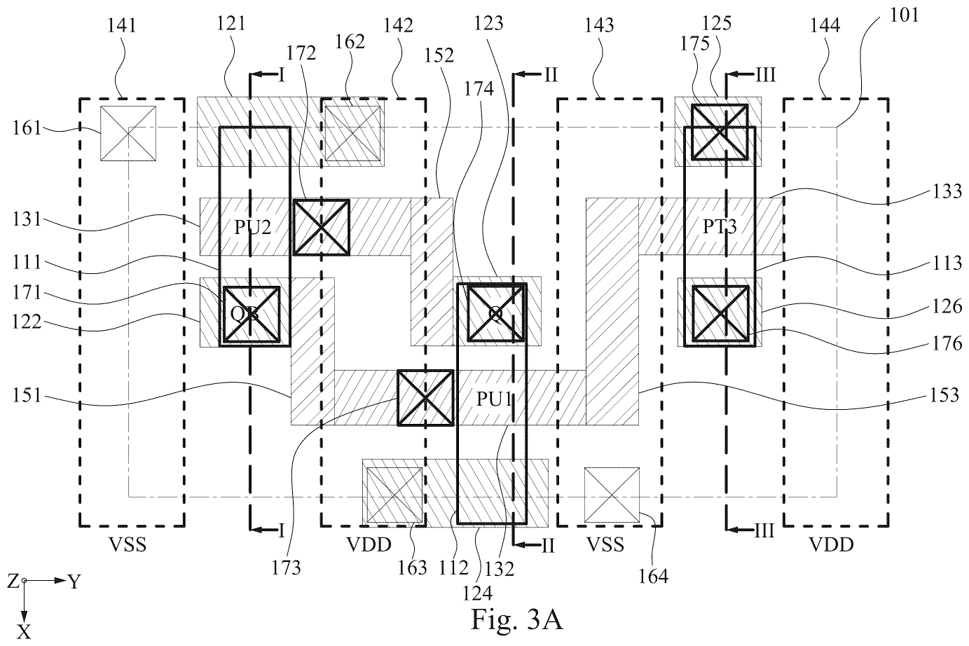

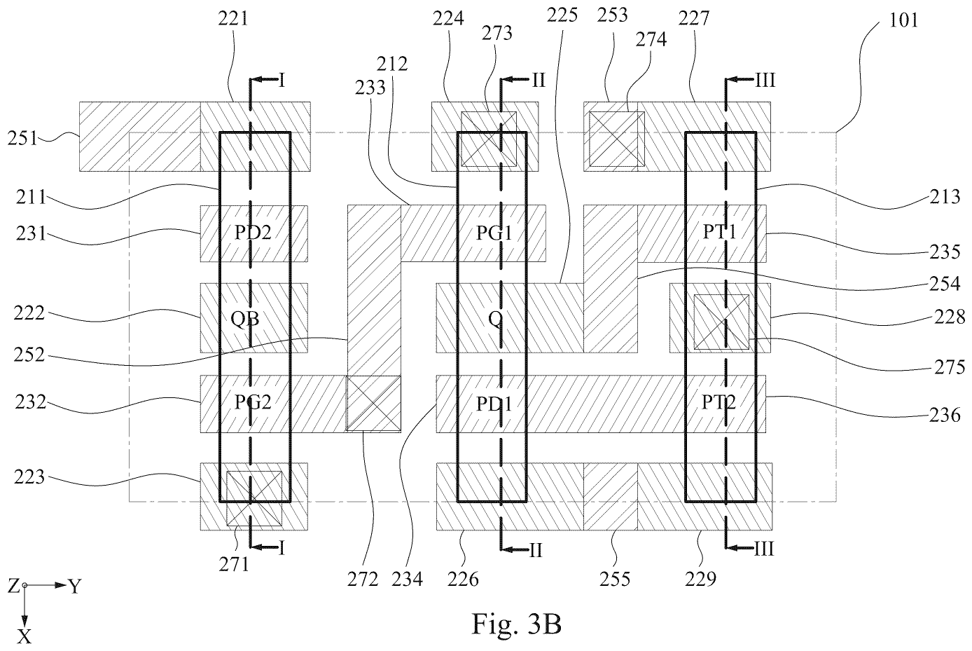

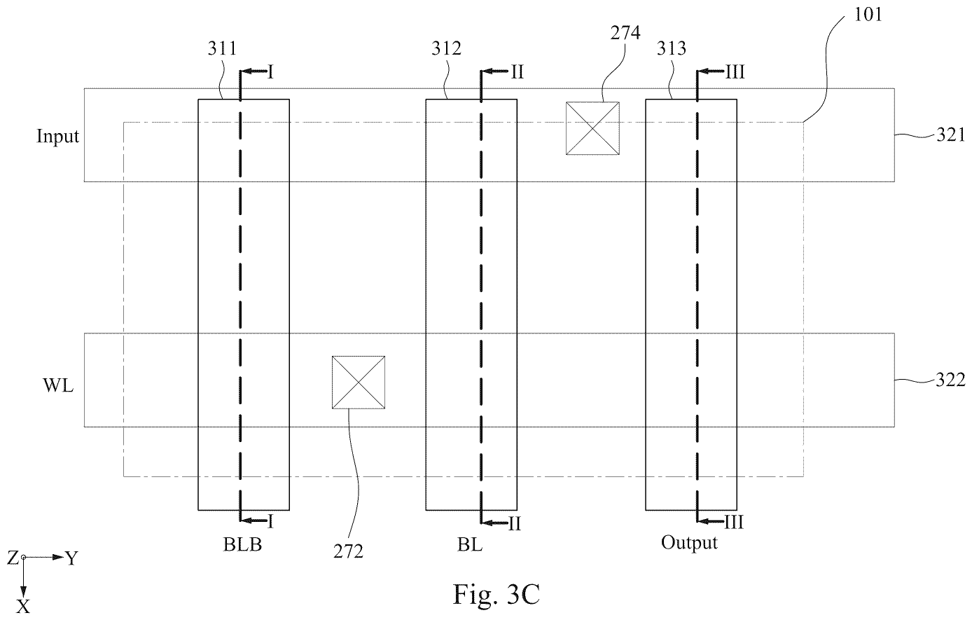

FIG. 2 is a perspective view of the memory device 10A of FIG. 1, in accordance with some embodiments of the present disclosure, FIG. 3A is a layout diagram of backside conductive lines and a first semiconductor level (or a bottom tier) of the memory device 10A of FIG. 1, FIG. 3B is a layout diagram of a second semiconductor level (or a top tier) of the memory device 10A of FIG. 1, and FIG. 3C is a layout diagram of front-side conductive lines of the memory device 10A of FIG. 1. As illustratively shown in FIGS. 2-3C, the memory device 10A includes the pull up transistors PU1 and PU2 and the pass transistor PT3 of FIG. 1 that are disposed in a first semiconductor level, and further the pull down transistors PD1 and PD2, the pass gate transistors PG1 and PG2, and the pass transistors PT1 and PT2 of FIG. 1 disposed in a second semiconductor level. In some embodiments, the first semiconductor level is different from and below the second semiconductor level along a vertical (z) direction. Alternatively stated, the pull down transistor PD1 is arranged above the pull up transistor PU1. The pull down transistor PD2 is arranged above the pull up transistor PU2. The pass transistor PT1 is arranged above the pass transistor PT3. The transistor PG1, PG2, and PT2 are not directly over the transistors in the first semiconductor level.

As depicted, each of the layout diagrams in FIGS. 3A-3C includes a cell boundary 101 defining a physical area of the memory cell MCA. In the layout diagram of FIG. 3A, the memory device 10A includes active regions (e.g., Oxide diffusion (OD)) 111-113, source/drain structures (e.g., metal-on-device (MD)) 121-126, gate structures 131-133 (e.g., polysilicon (PO)), conductive lines 141-144 (e.g., back side metal-zero layer (BM0)), connection structures 151-153, and conductive vias 161-164 and 171-176 that are coupling between structures in the memory device 10A.

In some embodiments, the conductive lines 141-144 are disposed in a first layer of a backside of the memory cell MCA. The conductive lines 141-144 extend in an X direction. The conductive lines 141 and 143 are configured to transmit a supply voltage VSS to the memory cell MCA, and the conductive lines 142 and 144 are configured to transmit a supply voltage VDD to the memory cell MCA. Therefore, the conductive lines 141 and 143 can be referred to as VSS conductive lines, and the conductive lines 142 and 144 can be referred to as VDD conductive lines. As shown in FIGS. 2 and 3A, the VSS conductive lines 141 and 143 and the VDD conductive lines 142 and 144 are alternately arranged in a Y direction.

In some embodiments, the active regions (or active areas or active structures or channel structures) 111-113 are disposed in a first layer of a front-side of the memory cell MCA and extend in the X direction. The first layer of the front-side of the memory cell MCA is over the first layer of the backside of the memory cell MCA. As shown in FIG. 3A, the active regions 111-113 are arranged in the Y direction. Further, the active region 111 is between the conductive lines 141 and 142 in the top view, the active region 112 is between the conductive lines 142 and 143 in the top view, and the active region 113 is between the conductive lines 143 and 144 in the top view. That is, the active regions 111-113 and the conductive lines 141-144 are alternately arranged in the y direction.

In some embodiments, the gate structures 131-133 are disposed in the first layer of the front-side and extend in the Y direction. The gate structure 131 is across the active region 111, the gate structure 132 is across the active region 112, and the gate structure 133 is across the active region 113. The gate structures 131 and 133 are aligned with each other in the Y direction but separated from each other. The gate structure 131 is electrically isolated from the gate structure 133. The gate structure 132 is misaligned with the gate structures 131 and 133 in the Y direction.

In some embodiments, the source/drain structures 121-126 cover the active regions 111-113 and disposed in the first layer of the front-side. The source/drain structures 121 and 122 are electrically connected to the active region 111 and on opposite sides of the gate structure 131, the source/drain structures 123 and 124 are electrically connected to the active region 112 and on opposite sides of the gate structure 132, and the source/drain structures 125 and 126 are electrically connected to the active region 113 and on opposite sides of the gate structure 133. The source/drain structures 122, 123, and 126 are aligned with each other in the y direction, and the source/drain structures 121 and 125 are aligned with each other in the Y direction.

Therefore, the active region 111, the gate structure 131, and the source/drain structures 121 and 122 form the transistor PU2, the active region 112, the gate structure 132, and the source/drain structures 123 and 124 form the transistor PU1, and the active region 113, the gate structure 133, and the source/drain structures 125 and 126 form the transistor PT3. The source/drain structure 121 may be referred to a source terminal of the transistor PU2, the source/drain structure 122 may be referred to a drain terminal of the transistor PU2, the source/drain structure 123 may be referred to a drain terminal of the transistor PU1, the source/drain structure 124 may be referred to a source terminal of the transistor PU1, the source/drain structure 125 may be referred to a source terminal of the transistor PT3, and the source/drain structure 126 may be referred to a drain terminal of the transistor PT3. The transistors PU2 and PT3 are aligned with each other in the Y direction, and the transistor PU1 is between the transistors PU2 and PT3 and is misaligned with the transistors PU2 and PT3 in the Y direction. The transistor PU1 is electrically connected to the transistors PU2 and PT3. For example, the source/drain structure 122 of the transistor PU2 is electrically connected to the gate structure 132 of the transistor PU1 and the gate structure 133 of the transistor PT3.

In some embodiments, the connection structures 151-153 are disposed in the first layer of the front-side and extend in the x direction. The connection structure 151 interconnects the source/drain structure 122 and the gate structure 132, the connection structure 152 interconnects the source/drain structure 123 and the gate structure 131, and the connection structure 153 interconnects the gate structures 132 and 133.

In some embodiments, the conductive vias 161-164 are disposed between the first layer of the front-side and the first layer of the backside, and may extend through the first layer of the front-side. As shown in FIGS. 2 and 3A, the conductive via 161 is electrically connected to the (VSS) conductive line 141 and extends upward to the second semiconductor level (FIG. 3B) of the memory device 10A, the conductive via 162 is electrically connected to the (VDD) conductive line 142 and the source/drain structure 121, the conductive via 163 is electrically connected to the (VDD) conductive line 142 and the source/drain structure 124, and the conductive via 164 is electrically connected to the (VSS) conductive line 143 and extends upward to the second semiconductor level of the memory device 10A.

In some embodiments, the conductive vias 171-176 are disposed in a second layer of the front-side above the first layer of the front-side. The first layer and the second layer of the front-side are in the first semiconductor level. The conductive via 171 is electrically connected to the source/drain structure 122, the conductive via 172 is electrically connected to the gate structure 131, the conductive via 173 is electrically connected to the gate structure 132, the conductive via 174 is electrically connected to the source/drain structure 123, the conductive via 175 is electrically connected to the source/drain structure 125, and the conductive via 176 is electrically connected to the source/drain structure 126.

In the layout diagram of FIG. 3B, the memory device 10A includes active regions (e.g., Oxide diffusion (OD)) 211-213, source/drain structures (e.g., metal-on-device (MD)) 221-229, gate structures 231-236 (e.g., polysilicon (PO)), connection structures 251-255, and conductive vias 271-275 that are coupling between structures in the memory device 10A.

In some embodiments, the active regions (or active areas or active structures or channel structures) 211-213 are disposed in a third layer of a front-side of the memory cell MCA and extend in the X direction. The third layer of the front-side of the memory cell MCA is over the second layer of the front-side of the memory cell MCA. As shown in FIG. 3B, the active regions 211-213 are arranged in the Y direction. Further, the active region 211 is above the active region 111, the active region 212 is above the active region 112, and the active region 213 is above the active region 113. That is, the active region 211 and 111 are aligned with each other in the Z direction, the active region 212 and 112 are aligned with each other in the Z direction, and the active region 213 and 113 are aligned with each other in the Z direction.

In some embodiments, the gate structures 231-236 are disposed in the third layer of the front-side and extend in the Y direction. The gate structures 231 and 232 are across the active region 211, the gate structures 233 and 234 are across the active region 212, and the gate structures 235 and 236 are across the active region 213. The gate structures 231, 233, and 235 are aligned with each other in the Y direction but separated from each other. The gate structures 232, 234, and 236 are aligned with each other in the Y direction. Further, the gate structure 234 is electrically connected to the gate structure 236.

In some embodiments, the source/drain structures 221-229 cover the active regions 211-213 and disposed in the third layer of the front-side. The source/drain structures 221 and 222 are electrically connected to the active region 211 and on opposite sides of the gate structure 231, the source/drain structures 222 and 223 are electrically connected to the active region 211 and on opposite sides of the gate structure 232, the source/drain structures 224 and 225 are electrically connected to the active region 212 and on opposite sides of the gate structure 233, the source/drain structures 225 and 226 are electrically connected to the active region 212 and on opposite sides of the gate structure 234, the source/drain structures 227 and 228 are electrically connected to the active region 213 and on opposite sides of the gate structure 235, and the source/drain structures 228 and 229 are electrically connected to the active region 213 and on opposite sides of the gate structure 236. The source/drain structures 221, 224, and 227 are aligned with each other in the Y direction, the source/drain structures 222, 225, and 228 are aligned with each other in the Y direction, and the source/drain structures 223, 226, and 229 are aligned with each other in the Y direction.

Therefore, the active region 211, the gate structure 231, and the source/drain structures 221 and 222 form the transistor PD2, the active region 211, the gate structure 232, and the source/drain structures 222 and 223 form the transistor PG2, the active region 212, the gate structure 233, and the source/drain structures 224 and 225 form the transistor PG1, the active region 212, the gate structure 234, and the source/drain structures 225 and 226 form the transistor PD1, the active region 213, the gate structure 235, and the source/drain structures 227 and 228 form the transistor PT1, and the active region 213, the gate structure 236, and the source/drain structures 228 and 229 form the transistor PT2.

The source/drain structure 221 may be referred to a source terminal of the transistor PD2, the source/drain structure 222 may be referred to a drain terminal of the transistor PD2 and a drain terminal of the transistor PG2 (i.e., the transistors PD2 and PG2 share the same source/drain structure 222), the source/drain structure 223 may be referred to a source terminal of the transistor PG2, the source/drain structure 224 may be referred to a source terminal of the transistor PG1, the source/drain structure 225 may be referred to a drain terminal of the transistor PG1 and a drain terminal of the transistor PD1 (i.e., the transistors PG1 and PD1 share the same source/drain structure 225), the source/drain structure 226 may be referred to a source terminal of the transistor PD1, the source/drain structure 227 may be referred to a source terminal of the transistor PT1, the source/drain structure 228 may be referred to a drain terminal of the transistor PT1 and a drain terminal of the transistor PT2 (i.e., the transistors PT1 and PT2 share the same source/drain structure 228), and the source/drain structure 229 may be referred to a source terminal of the transistor PT2.

The transistors PD2, PG1, and PT1 are aligned with each other in the Y direction, the transistors PG2, PD1, and PT2 are aligned with each other in the Y direction, the transistors PD2 and PG2 are aligned with each other in the X direction, the transistors PG1 and PD1 are aligned with each other in the X direction, and the transistors PT1 and PT2 are aligned with each other in the X direction.

As shown in FIGS. 2-3B, the conductive via 171 interconnects the source/drain structures 122 and 222, the conductive via 172 interconnects the gate structures 131 and 231, the conductive via 173 interconnects the gate structures 132 and 234, the conductive via 174 interconnects the source/drain structures 123 and 225, the conductive via 175 interconnects the source/drain structures 125 and 227, and the conductive via 176 interconnects the source/drain structures 126 and 228.

In some embodiments, the connection structures 251-255 are disposed in the third layer of the front-side. The connection structure 251 interconnects the source/drain structure 221 and the conductive via 161, the connection structure 252 interconnects the gate structures 232 and 233, the connection structure 253 is electrically connected to the source/drain structure 227, the connection structure 254 interconnects the source/drain structure 225 and the gate structure 235, and the connection structure 255 interconnects the source/drain structure 226 and 229.

In some embodiments, the conductive vias 271-275 are disposed in a fourth layer of the front-side above the third layer of the front-side. The third layer and the fourth layer of the front-side are in the second semiconductor level. The conductive via 271 is electrically connected to the source/drain structure 223, the conductive via 272 is electrically connected to the connection structure 252, the conductive via 273 is electrically connected to the source/drain structure 224, the conductive via 274 is electrically connected to the connection structure 253, and the conductive via 275 is electrically connected to the source/drain structure 228.

In the layout diagram of FIG. 3C, the memory device 10A includes the conductive lines (or rails) 311-313 (e.g., metal-one layer (M1)), conductive lines (or rails) 321 and 322 (e.g., metal-one layer (M1)), and the conductive vias 272 and 274.

In some embodiments, the conductive lines 311-313 are disposed in a M1 level of the memory cell MCA and above the second semiconductor level. The conductive lines 311-313 extend in the X direction. The conductive line 311 corresponds to the bit line BLB, the conductive line 312 corresponds to the bit line BL, and the conductive line 313 is configured to transmit an output signal from the memory cell MCA.

In some embodiments, the conductive lines 321 and 322 are disposed in a M2 level of the memory device 10A and above the M1 level. The conductive lines 321 and 322 extend in the Y direction. The conductive line 321 is configured to transmit an input signal to the memory cell MCA, and the conductive line 322 corresponds to the word line WL.

In FIGS. 2, 3B, and 3C, the conductive via 271 interconnects the source/drain structure 223 and the conductive line 311 (i.e., the bit line BLB), the conductive via 272 interconnects the gate structures 232 and 233 and the conductive line 322 (i.e., the word line WL), the conductive via 273 interconnects the source/drain structure 224 and the conductive line 312 (i.e., the bit line BL), the conductive via 274 interconnects the source/drain structure 227 and the conductive line 321, and the conductive via 275 interconnects the source/drain structure 228 and the conductive line 313.

As shown in FIGS. 1 and 3A, the memory device 10A includes the pass transistor PT3 electrically connected to the pass transistor PT1 and the node QB. The pass transistor PT3 is disposed under the pass transistor PT1, such that the layout area of 8T-SRAM (i.e., the memory device including the transistors PU1-PU2, PD1-PD2, PG1-PG2, and PT1-PT2) is the same as the layout area of 9T-SRAM (i.e., the memory device 10A including the transistors PU1-PU2, PD1-PD2, PG1-PG2, and PT1-PT3).

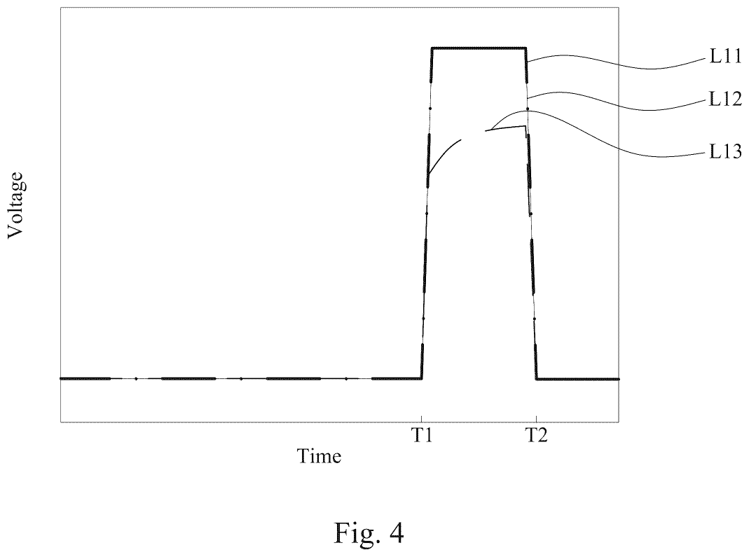

FIG. 4 is a graph illustrating input/output voltages with time of the memory devices with/without the pass transistor PT3. As shown in FIGS. 1 and 4, during the time period T1-T2, an input signal is input from the input terminal (e.g., through the conductive line 321), and an output signal is detected from the output terminal (e.g., through the conductive line 313). In FIG. 4, line L11 represents the input signal, line L12 represents the output signal of the memory device with the pass transistor PT3, and line L13 represents the output signal of the memory device without the pass transistor PT3. Without the pass transistor PT3, the output signal has a voltage degradation issue, and with the pass transistor PT3, the voltage degradation issue of the output signal is improved or solved. That is, the pass transistor PT3 improves the output signal degradation issue while not increasing the layout area of the memory device 10A.

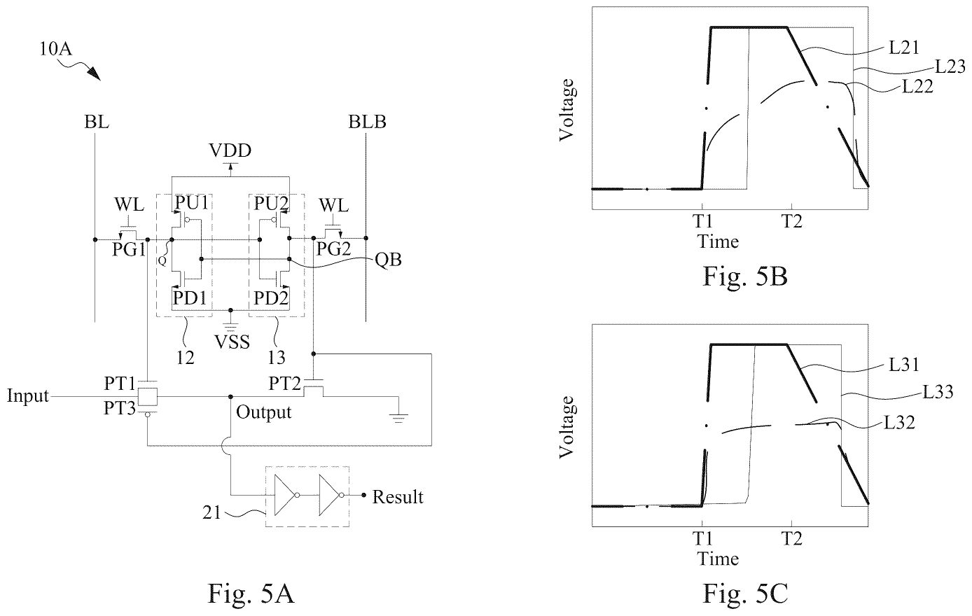

FIG. 5A is a schematic diagram of part of the memory device 10A of FIG. 1 and an inverter chain 21, in accordance with some embodiments of the present disclosure. The inverter chain 21 is connected to the output terminal of the memory device 10A and is used to imitate the logic gates after multiplication. FIG. 5B is a graph illustrating input/output/result voltages with time of the memory device 10A when the input voltage is about 0.8V and the VDD is about 0.5 V, and FIG. 5C is a graph illustrating input/output/result voltages with time of the memory device 10A when the input voltage is about 0.8V and the VDD is about 0.6 V. In FIGS. 5B and 5C, during the time period T1-T2, an input signal is input from the input terminal. The voltages at VDD terminal of the memory device 10A are lower than the input voltage (i.e., the (VDD) voltage of the logic circuit connected to the memory device 10A). Lines L21 and L31 represent the input voltages, lines L22 and L32 represent the output voltages, and lines L23 and L33 represent the voltages at result terminal. As shown in FIGS. 5B and 5C, the voltages at result terminal (i.e., lines L23 and L33) still reflect the signal of the input voltage when the input voltage is higher than the voltages at VDD terminal. Therefore, the memory device 10A still has the potential to do high-performance computing when the input voltage is higher than the voltages at VDD terminal, reducing leakage power for memory storage. With high input voltages, the memory device 10A has an ability to do high speed computing without losing result signals.

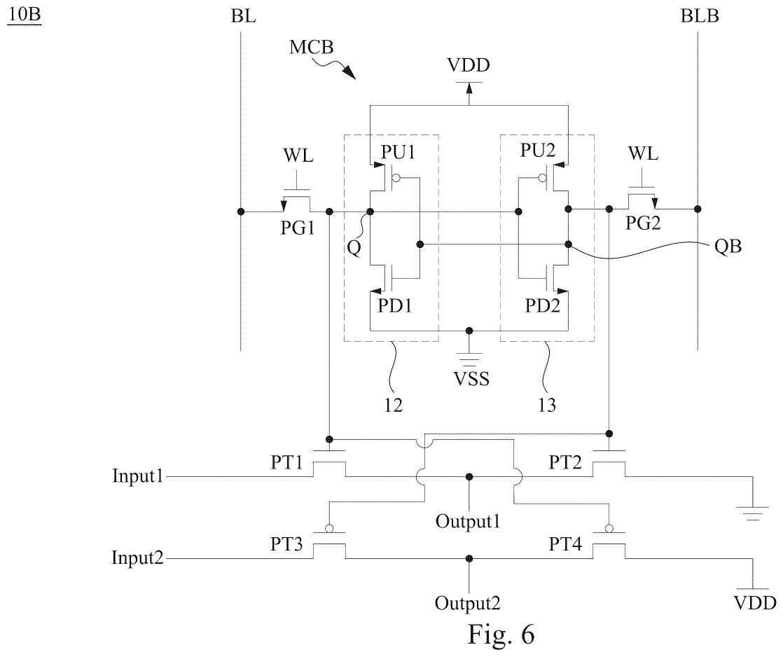

FIG. 6 is a schematic diagram of part of a memory device 10B, in accordance with some embodiments of the present disclosure. For illustration, a memory cell MCB in the memory device 10B is coupled to bit lines BL and BLB. In some embodiments, the memory cell MCB includes an inverter 12 and an inverter 13. The inverter 12 and the inverter 13 are cross-coupled. Effectively, the inverter 12 and the inverter 13 operate as a data latch. For illustration, an output node of the inverter 12 and an input node of the inverter 13 are connected together at a node Q shown in FIG. 6. An input node of the inverter 12 and an output node of the inverter 13 are connected together at a node QB shown in FIG. 6.

In some embodiments, the memory cell MCB illustrated in FIG. 6 is a static random-access memory (SRAM) cell, including, for illustration, ten transistors (10T) PU1-PU2, PD1-PD2, PG1-PG2, and PT1-PT4. The pull up transistor PU1 and the pull down transistor PD1 are configured and operate as the inverter 12. The pull up transistor PU2 and the pull down transistor PD2 are configured and operate the inverter 13. In some embodiments, the pull down transistors PD1-PD2, the pass gate transistors PG1-PG2, and the pass transistors PT1-PT2 are N-type transistors, and the pull up transistors PU1-PU2 and the pass transistors PT3-PT4 are P-type transistors, or vice versa. It is noted that the transistors PU1-PU2, PD1-PD2, PG1-PG2, and PT1-PT10 may be FinFETs, GAA FETs, TreeFETs, or other suitable transistors.

In some embodiments, the transistor PG1 is configured as a first pass gate transistor, and the transistor PG2 is configured as a second pass gate transistor. For illustration, gate terminals of the transistor PG1 and the transistor PG2 are coupled to a word line WL and controlled by a word line signal. The output node of the inverter 12 and the input node of the inverter 13, i.e., the node Q, are coupled through the transistor PG1 to the bit line BL. The input node of the inverter 12 and the output node of the inverter 13, i.e., the node QB, are coupled through the transistor PG2 to the complementary bit line BLB.

The pass transistors PT1-PT4 are used for DCIM applications. The gate terminals of the pass transistors PT1 and PT4 are coupled to the node Q, and the gate terminals of the pass transistors PT2 and PT3 are coupled to the node QB. The first input terminal Input1 of the memory device 10B is coupled through the pass transistor PT1 to the first output terminal Output1 of the memory device 10B, which is coupled through the pass transistor PT2 to the ground (e.g., the supply voltage VSS in this case). The second input terminal Input2 of the memory device 10B is coupled through the pass transistor PT3 to the second output terminal Output2 of the 10B, which is coupled through the pass transistor PT4 to the supply voltage VDD.

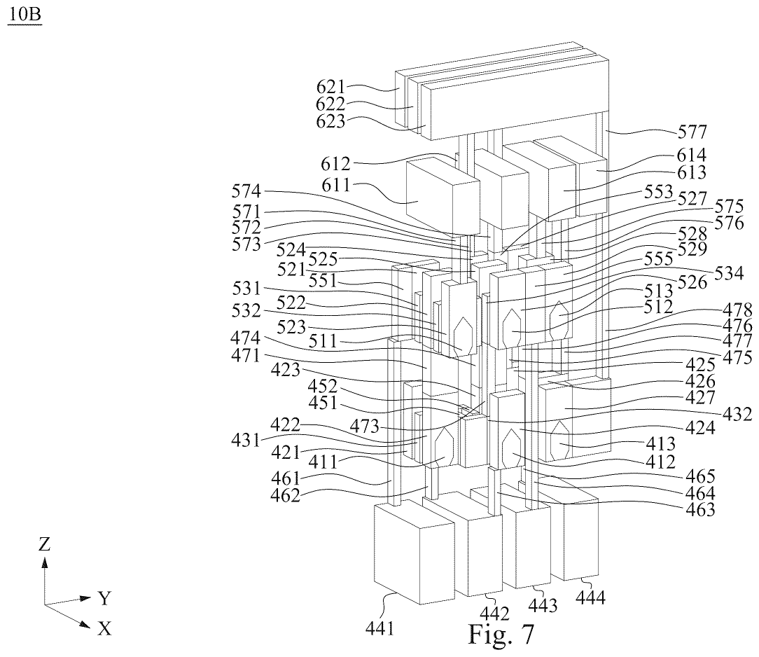

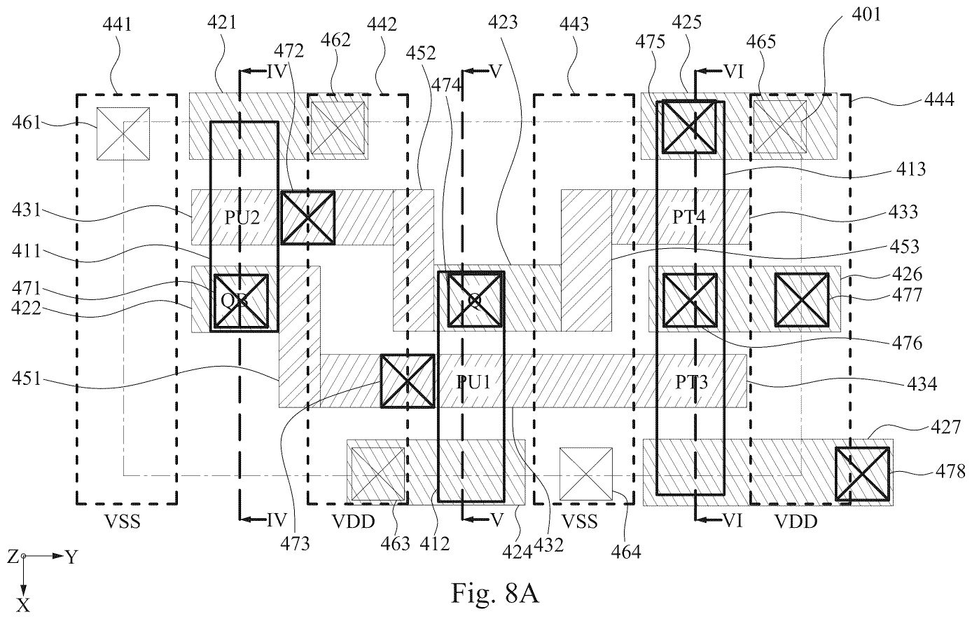

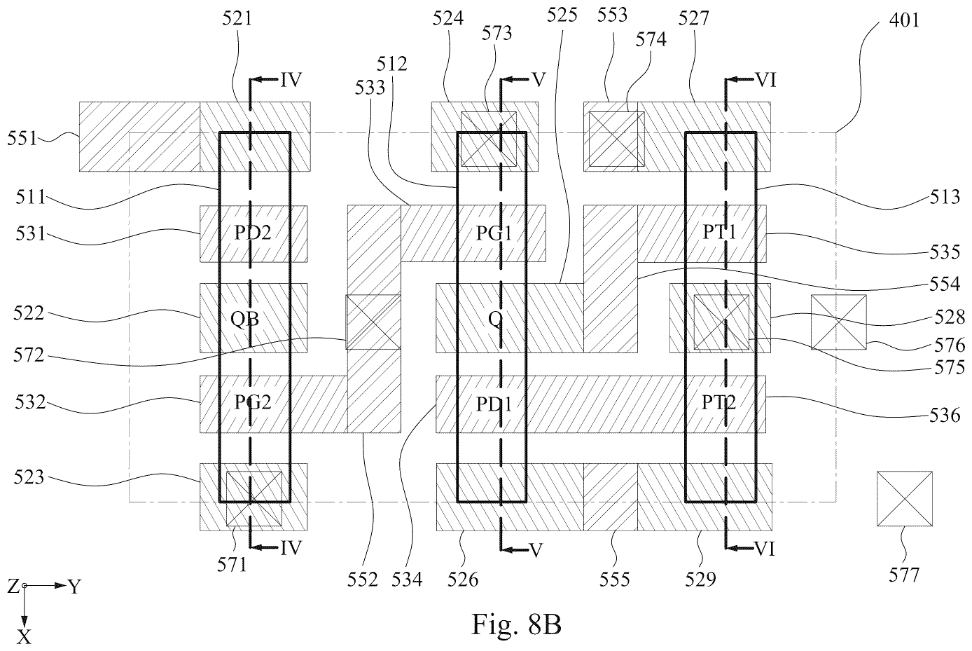

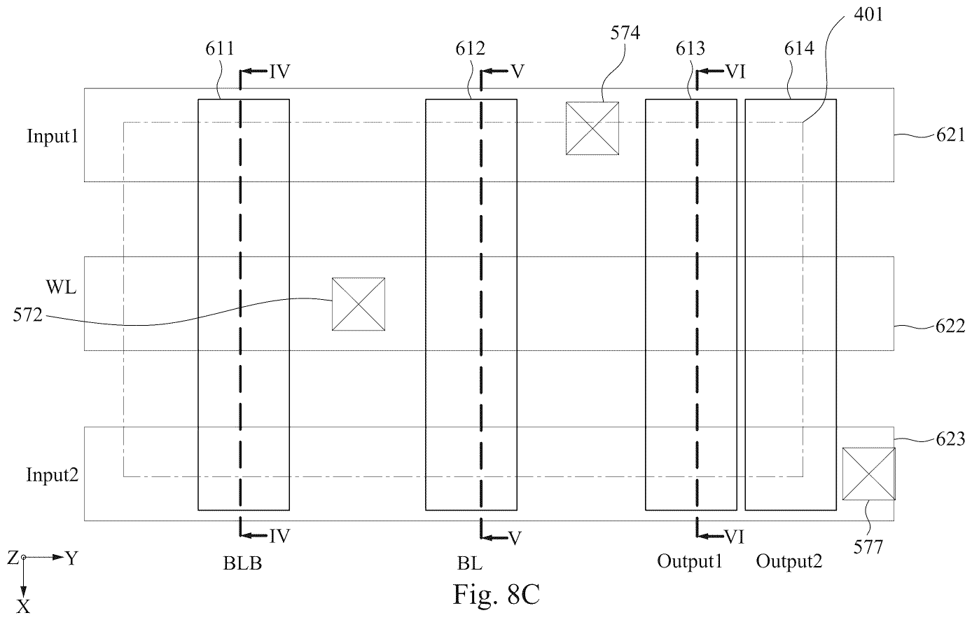

FIG. 7 is a perspective view of the memory device 10B of FIG. 6, in accordance with some embodiments of the present disclosure, FIG. 8A is a layout diagram of backside conductive lines and a first semiconductor level (or a bottom tier) of the memory device 10B of FIG. 6, FIG. 8B is a layout diagram of a second semiconductor level (or a top tier) of the memory device 10B of FIG. 6, and FIG. 8C is a layout diagram of front-side conductive lines of the memory device 10B of FIG. 6. As illustratively shown in FIGS. 7-8C, the memory device 10B includes the pull up transistors PU1 and PU2 and the pass transistors PT3 and PT4 of FIG. 6 that are disposed in a first semiconductor level, and further the pull down transistors PD1 and PD2, the pass gate transistors PG1 and PG2, and the pass transistors PT1 and PT2 of FIG. 6 disposed in a second semiconductor level. In some embodiments, the first semiconductor level is different from and below the second semiconductor level along a vertical (Z) direction. Alternatively stated, the pull down transistor PD1 is arranged above the pull up transistor PU1. The pull down transistor PD2 is arranged above the pull up transistor PU2. The pass transistor PT1 is arranged above the pass transistor PT4. The pass transistor PT2 is arranged above the pass transistor PT3. The transistor PG1 and PG2 are not directly over the transistors in the first semiconductor level.

As depicted, each of the layout diagrams in FIGS. 8A-8C includes a cell boundary 401 defining a physical area of the memory cell MCB. In the layout diagram of FIGS. 7 and 8A, the memory device 10B includes active regions (e.g., Oxide diffusion (OD)) 411-413, source/drain structures (e.g., metal-on-device (MD)) 421-427, gate structures 431-434 (e.g., polysilicon (PO)), conductive lines 441-444 (e.g., back side metal-zero layer (BM0)), connection structures 451-453, and conductive vias 461-465 and 471-478 that are coupling between structures in the memory device 10B.

In some embodiments, the conductive lines 441-444 are disposed in a first layer of a backside of the memory cell MCB. The conductive lines 441-444 extend in an X direction. The conductive lines 441 and 443 are configured to transmit a supply voltage VSS to the memory cell MCB, and the conductive lines 442 and 444 are configured to transmit a supply voltage VDD to the memory cell MCB. Therefore, the conductive lines 441 and 443 can be referred to as VSS conductive lines, and the conductive lines 442 and 444 can be referred to as VDD conductive lines. As shown in FIGS. 7 and 8A, the VSS conductive lines 441 and 443 and the VDD conductive lines 442 and 444 are alternately arranged in a Y direction.

In some embodiments, the active regions (or active areas or active structures or channel structures) 411-413 are disposed in a first layer of a front-side of the memory cell MCB and extend in the X direction. The first layer of the front-side of the memory cell MCB is over the first layer of the backside of the memory cell MCB. As shown in FIG. 8A, the active regions 411-413 are arranged in the Y direction. Further, the active region 411 is between the conductive lines 441 and 442 in the top view, the active region 412 is between the conductive lines 442 and 443 in the top view, and the active region 413 is between the conductive lines 443 and 444 in the top view. That is, the active regions 411-413 and the conductive lines 441-444 are alternately arranged in the Y direction.

In some embodiments, the gate structures 431-434 are disposed in the first layer of the front-side and extend in the Y direction. The gate structure 431 is across the active region 411, the gate structure 432 is across the active region 412, and the gate structures 433 and 434 are across the active region 413. The gate structures 431 and 433 are aligned with each other in the Y direction but separated from each other. The gate structures 432 and 434 are aligned with each other in the Y direction and are electrically connected to each other.

In some embodiments, the source/drain structures 421-427 cover the active regions 411-413 and disposed in the first layer of the front-side. The source/drain structures 421 and 422 are electrically connected to the active region 411 and on opposite sides of the gate structure 431, the source/drain structures 423 and 424 are electrically connected to the active region 412 and on opposite sides of the gate structure 432, the source/drain structures 425 and 426 are electrically connected to the active region 413 and on opposite sides of the gate structure 433, and the source/drain structures 426 and 427 are electrically connected to the active region 413 and on opposite sides of the gate structure 434. The source/drain structures 422, 423, and 426 are aligned with each other in the Y direction, the source/drain structures 421 and 425 are aligned with each other in the Y direction, and the source/drain structures 424 and 427 are aligned with each other in the Y direction.

Therefore, the active region 411, the gate structure 431, and the source/drain structures 421 and 422 form the transistor PU2, the active region 412, the gate structure 432, and the source/drain structures 423 and 424 form the transistor PU1, the active region 413, the gate structure 433, and the source/drain structures 425 and 426 form the transistor PT4, and the active region 413, the gate structure 434, and the source/drain structures 426 and 427 form the transistor PT3. The source/drain structure 421 may be referred to a source terminal of the transistor PU2, the source/drain structure 422 may be referred to a drain terminal of the transistor PU2, the source/drain structure 423 may be referred to a drain terminal of the transistor PU1, the source/drain structure 424 may be referred to a source terminal of the transistor PU1, the source/drain structure 425 may be referred to a source terminal of the transistor PT4, the source/drain structure 426 may be referred to a drain terminal of the transistor PT4 and a drain terminal of the transistor PT3 (i.e., the transistors PT4 and PT3 share the same source/drain structure 426), and the source/drain structure 427 may be referred to a source terminal of the transistor PT3. The transistors PU2 and PT4 are aligned with each other in the Y direction, and the transistors PU1 and PT3 are aligned with each other in the Y direction. The transistor PU1 is electrically connected to the transistors PU2, PT3, and PT4. For example, the source/drain structure 422 of the transistor PU2 is electrically connected to the gate structure 432 of the transistor PU1 and the gate structure 434 of the transistor PT3, and the gate structure 431 of the transistor PU2 is electrically connected to the source/drain structure 423 of the transistor PU1 and the gate structure 433 of the transistor PT4.

In some embodiments, the connection structures 451-453 are disposed in the first layer of the front-side and extend in the X direction. The connection structure 451 interconnects the source/drain structure 422 and the gate structure 432, the connection structure 452 interconnects the source/drain structure 423 and the gate structure 431, and the connection structure 453 interconnects the source/drain structure 423 and the gate structure 433.

In some embodiments, the conductive vias 461-465 are disposed between the first layer of the front-side and the first layer of the backside, and may extend through the first layer of the front-side. As shown in FIGS. 7 and 8A, the conductive via 461 is electrically connected to the (VSS) conductive line 441 and extends upward to the second semiconductor level (FIG. 8B) of the memory device 10B, the conductive via 462 is electrically connected to the (VDD) conductive line 442 and the source/drain structure 421, the conductive via 463 is electrically connected to the (VDD) conductive line 442 and the source/drain structure 424, the conductive via 464 is electrically connected to the (VSS) conductive line 443 and extends upward to the second semiconductor level of the memory device 10B, and the conductive via 465 is electrically connected to the (VDD) conductive line 444 and the source/drain structure 425.

In some embodiments, the conductive vias 471-478 are disposed in a second layer of the front-side above the first layer of the front-side. The first layer and the second layer of the front-side are in the first semiconductor level. The conductive via 471 is electrically connected to the source/drain structure 422, the conductive via 472 is electrically connected to the gate structure 431, the conductive via 473 is electrically connected to the gate structure 432, the conductive via 474 is electrically connected to the source/drain structure 423, the conductive via 475 is electrically connected to the source/drain structure 425, the conductive vias 476 and 477 are electrically connected to the source/drain structure 426, and the conductive via 478 is electrically connected to the source/drain structure 427.

In the layout diagram of FIG. 8B, the memory device 10B includes active regions (e.g., Oxide diffusion (OD)) 511-513, source/drain structures (e.g., metal-on-device (MD)) 521-529, gate structures 531-536 (e.g., polysilicon (PO)), connection structures 551-555, and conductive vias 571-577 that are coupling between structures in the memory device 10B.

In some embodiments, the active regions (or active areas or active structures or channel structures) 511-513 are disposed in a third layer of a front-side of the memory cell MCB and extend in the X direction. The third layer of the front-side of the memory cell MCB is over the second layer of the front-side of the memory cell MCB. As shown in FIGS. 7 and 8B, the active regions 511-513 are arranged in the Y direction. Further, the active region 511 is above the active region 411, the active region 512 is above the active region 412, and the active region 513 is above the active region 413. That is, the active region 511 and 411 are aligned with each other in the Z direction, the active region 512 and 412 are aligned with each other in the Z direction, and the active region 513 and 413 are aligned with each other in the Z direction.

In some embodiments, the gate structures 531-536 are disposed in the third layer of the front-side and extend in the Y direction. The gate structures 531 and 532 are across the active region 511, the gate structures 533 and 534 are across the active region 512, and the gate structures 535 and 536 are across the active region 513. The gate structures 531, 533, and 535 are aligned with each other in the Y direction but separated from each other. The gate structures 532, 534, and 536 are aligned with each other in the Y direction. Further, the gate structure 534 is electrically connected to the gate structure 536.

In some embodiments, the source/drain structures 521-529 cover the active regions 511-513 and disposed in the third layer of the front-side. The source/drain structures 521 and 522 are electrically connected to the active region 511 and on opposite sides of the gate structure 531, the source/drain structures 522 and 523 are electrically connected to the active region 511 and on opposite sides of the gate structure 532, the source/drain structures 524 and 525 are electrically connected to the active region 512 and on opposite sides of the gate structure 533, the source/drain structures 525 and 526 are electrically connected to the active region 512 and on opposite sides of the gate structure 534, the source/drain structures 527 and 528 are electrically connected to the active region 513 and on opposite sides of the gate structure 535, and the source/drain structures 528 and 529 are electrically connected to the active region 513 and on opposite sides of the gate structure 536. The source/drain structures 521, 524, and 527 are aligned with each other in the Y direction, the source/drain structures 522, 525, and 528 are aligned with each other in the Y direction, and the source/drain structures 523, 526, and 529 are aligned with each other in the Y direction.

Therefore, the active region 511, the gate structure 531, and the source/drain structures 521 and 522 form the transistor PD2, the active region 511, the gate structure 532, and the source/drain structures 522 and 523 form the transistor PG2, the active region 512, the gate structure 533, and the source/drain structures 524 and 525 form the transistor PG1, the active region 512, the gate structure 534, and the source/drain structures 525 and 526 form the transistor PD1, the active region 513, the gate structure 535, and the source/drain structures 527 and 528 form the transistor PT1, and the active region 513, the gate structure 536, and the source/drain structures 528 and 529 form the transistor PT2.

The source/drain structure 521 may be referred to a source terminal of the transistor PD2, the source/drain structure 522 may be referred to a drain terminal of the transistor PD2 and a drain terminal of the transistor PG2 (i.e., the transistors PD2 and PG2 share the same source/drain structure 522), the source/drain structure 523 may be referred to a source terminal of the transistor PG2, the source/drain structure 524 may be referred to a source terminal of the transistor PG1, the source/drain structure 525 may be referred to a drain terminal of the transistor PG1 and a drain terminal of the transistor PD1 (i.e., the transistors PG1 and PD1 share the same source/drain structure 525), the source/drain structure 526 may be referred to a source terminal of the transistor PD1, the source/drain structure 527 may be referred to a source terminal of the transistor PT1, the source/drain structure 528 may be referred to a drain terminal of the transistor PT1 and a drain terminal of the transistor PT2 (i.e., the transistors PT1 and Pt2 share the same source/drain structure 528), and the source/drain structure 529 may be referred to a source terminal of the transistor PT2.

The transistors PD2, PG1, and PT1 are aligned with each other in the Y direction, the transistors PG2, PD1, and PT2 are aligned with each other in the Y direction, the transistors PD2 and PG2 are aligned with each other in the X direction, the transistors PG1 and PD1 are aligned with each other in the X direction, and the transistors PT1 and PT2 are aligned with each other in the X direction.

As shown in FIGS. 7-8B, the conductive via 471 interconnects the source/drain structures 422 and 522, the conductive via 472 interconnects the gate structures 431 and 531, the conductive via 473 interconnects the gate structures 432 and 534, the conductive via 474 interconnects the source/drain structures 423 and 525, the conductive via 475 interconnects the source/drain structures 425 and 527, and the conductive via 476 interconnects the source/drain structures 426 and 528, the conductive via 477 interconnects the conductive via 576 and the source/drain structure 426, and the conductive via 478 interconnects the conductive via 577 and the source/drain structure 427.

In some embodiments, the connection structures 551-555 are disposed in the third layer of the front-side. The connection structure 551 interconnects the source/drain structure 521 and the conductive via 461, the connection structure 552 interconnects the gate structures 532 and 533, the connection structure 553 is electrically connected to the source/drain structure 527, the connection structure 554 interconnects the source/drain structure 525 and the gate structure 535, and the connection structure 555 interconnects the source/drain structure 526 and 529.

In some embodiments, the conductive vias 571-577 are disposed in a fourth layer of the front-side above the third layer of the front-side. The third layer and the fourth layer of the front-side are in the second semiconductor level. The conductive via 571 is electrically connected to the source/drain structure 523, the conductive via 572 is electrically connected to the connection structure 552, the conductive via 573 is electrically connected to the source/drain structure 524, the conductive via 574 is electrically connected to the connection structure 553, the conductive via 575 is electrically connected to the source/drain structure 528, the conductive via 576 is electrically connected to the conductive via 477, and the conductive via 577 is electrically connected to the conductive via 478.

In the layout diagram of FIG. 8C, the memory device 10B includes the conductive lines (or rails) 611-614 (e.g., metal-one layer (M1)), conductive lines (or rails) 621-623 (e.g., metal-one layer (M1)), and the conductive vias 572, 574, and 577.

In some embodiments, the conductive lines 611-614 are disposed in a M1 level of the memory cell MCB and above the second semiconductor level. The conductive lines 611-614 extend in the X direction. The conductive line 611 corresponds to the bit line BLB, the conductive line 612 corresponds to the bit line BL, the conductive line 613 is configured to transmit a first output signal Output1 from the memory cell MCB, and the conductive line 614 is configured to transmit a second output signal Output2 from the memory cell MCB.

In some embodiments, the conductive lines 621-623 are disposed in a M2 level of the memory cell MCB and above the M1 level. The conductive lines 621-623 extend in the Y direction. The conductive line 621 is configured to transmit a first input signal Input1 to the memory cell MCB, the conductive line 622 corresponds to the word line WL, and the conductive line 623 is configured to transmit a second input signal Input2 to the memory cell MCB.

In FIGS. 7, 8B, and 8C, the conductive via 571 interconnects the source/drain structure 523 and the conductive line 611 (i.e., the bit line BLB), the conductive via 572 interconnects the gate structures 532 and 533 and the conductive line 622 (i.e., the word line WL), the conductive via 573 interconnects the source/drain structure 524 and the conductive line 612 (i.e., the bit line BL), the conductive via 574 interconnects the source/drain structure 527 and the conductive line 621, the conductive via 575 interconnects the source/drain structure 528 and the conductive line 613, the conductive via 576 interconnects the source/drain structure 426 and the conductive line 614, and the conductive via 577 interconnects the source/drain structure 427 and the conductive line 623.

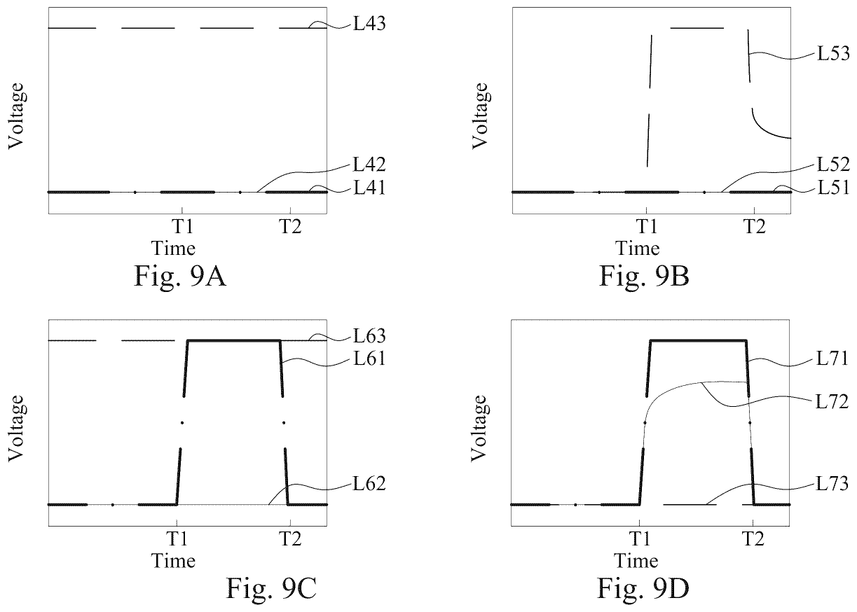

FIGS. 9A-9D are graphs illustrating computing signals of the memory device 10B, in accordance with some embodiments of the present disclosure. In FIGS. 9A-9D, during the time period T1-T2, input signals are input from the input terminals. Lines L41, L51, L61, and L71 represent input1 voltages, lines L42, L52, L62, and L72 represent output1 voltages, and lines L43, L53, L63, and L73 represent output2 voltages. Further, when the input1 signal is 1, the input2 signal is 0. In FIG. 9A, the input1 signal is 0 (i.e., the input2 signal is 1), the node Q is 0, the node QB is 1, the output1 signal results 0, and the output2 signal results 1. In FIG. 9B, the input1 signal is 0 (i.e., the input2 signal is 1), the node Q is 1, the node QB is 0, the output1 signal results 0, and the output2 signal results 1. In FIG. 9C, the input1 signal is 1 (i.e., the input2 signal is 0), the node Q is 0, the node QB is 1, the output1 signal results 0, and the output2 signal results 1. In FIG. 9D, the input1 signal is 1 (i.e., the input2 signal is 0), the node Q is 1, the node QB is 0, the output1 signal results 1, and the output2 signal results 0. As shown in FIGS. 9A-9D, the memory device 10B is able to compute dual DCIM applications (i.e., the two output signals) without increasing the layout area of the memory device 10B.

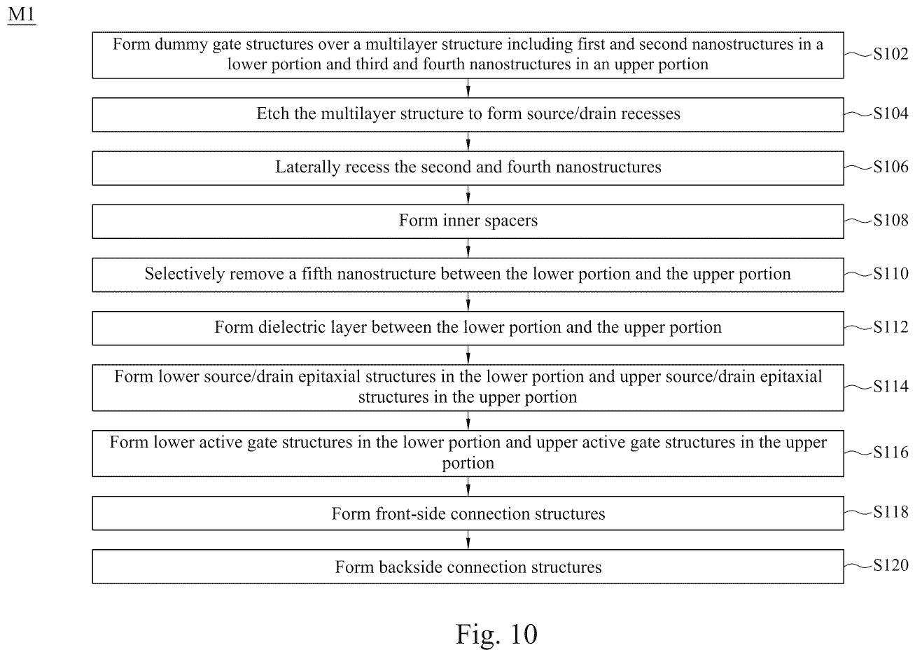

FIG. 10 illustrates a flowchart of a method M1 for forming a memory cell configured in a CFET structure, in accordance with some embodiments of the present disclosure. For example, at least some of the operations (or steps) of the method M1 can be used to form the memory device 10A (FIG. 2) or the memory device 10B (FIG. 7) in the CFET structure, which includes a number of p-type transistors disposed at the first semiconductor level on the front-side of the device and a number of n-type transistors disposed at the second, upper semiconductor level on the front-side of the device.

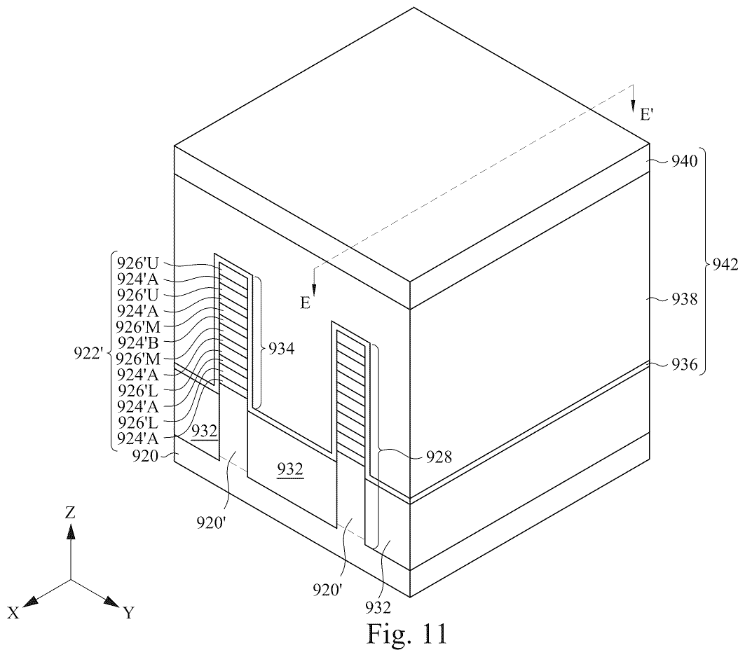

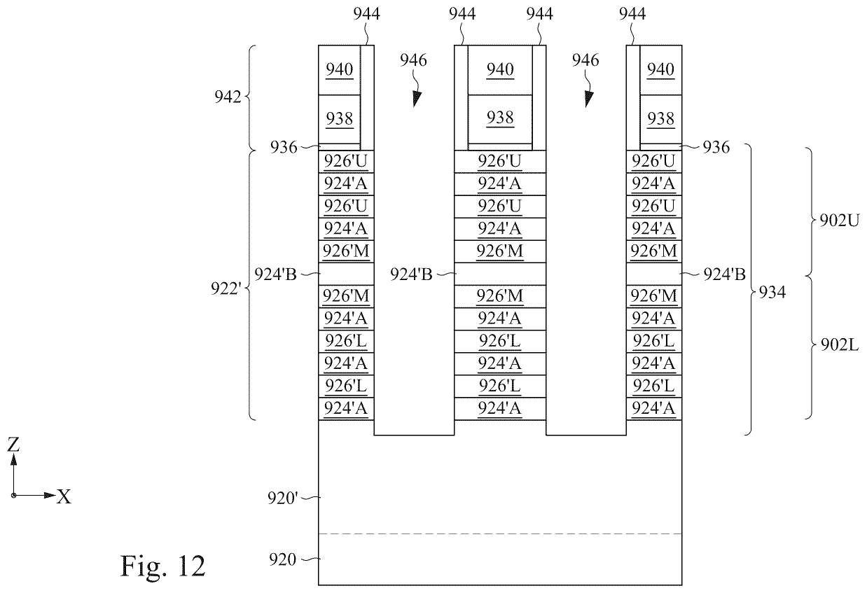

It is noted that the method M1 is merely an example and is not intended to limit the present disclosure. Accordingly, it is understood that additional operations may be provided before, during, and after the method M1, and that some other operations may only be briefly described herein. In some embodiments, operations of the method M1 may be associated with perspective and cross-sectional views of the memory devices 10A and/or 10B at various fabrication stages as shown in FIGS. 11-16, which are discussed in detail below. Further, FIGS. 12-16 are cross-sectional views of intermediate stages in the formation of the memory device taken along line E-E in FIG. 11 in accordance with some embodiments of the present disclosure.

Referring to FIGS. 10 and 11, dummy gate structures are formed over a multilayer structure including first and second nanostructures in a lower portion and third and fourth nanostructures in an upper portion at operation S102. Specifically, the multilayer structure 922′ includes a lower portion having alternating first semiconductor material (e.g., the first semiconductor layers or first nanostructures 924′A) and second semiconductor material (e.g., the second semiconductor layers or second nanostructures 926′L); an upper portion having alternating first semiconductor material (e.g., the third semiconductor layers or third nanostructures 924′A) and second semiconductor material (e.g., the fourth semiconductor layers or fourth nanostructures 926′U); and an intermediate layer of a third semiconductor material (e.g., a middle first semiconductor layer 924′B) different from the first semiconductor material and the second semiconductor material in composition. The intermediate layer of the third semiconductor material is interleaved between two layers (e.g., middle second semiconductor layers 926′M) of the second semiconductor material that are configured as dummy layers.

The multilayer structure 922′ is formed over the substrate 920. In FIG. 11, the multilayer structure 922′ is illustrated in a state after formation of semiconductor fins, as described herein. The multilayer structure 922′ includes alternatingly arranged first semiconductor layers 924′A and second semiconductor layers 926′L in the lower portion 902L (see FIG. 12), corresponding to the first semiconductor level, and alternatingly arranged third semiconductor layers 924′A and fourth semiconductor layers 926′U in the upper portion 902U (see FIG. 12), corresponding to the second semiconductor level. The second semiconductor layers 926′U and fourth semiconductor layers 926′L correspond to the nanostructures described with respect to FIG. 11. The first semiconductor materials, the second semiconductor materials, and the third semiconductor materials include semiconductor materials having different etch selectivity and/or oxidation rates. In some embodiments, the first semiconductor materials, the second semiconductor materials, and the third semiconductor materials include Si, Ge, Sn, Si₁₋ₓGeₓ, Si_{1-x-y}GeₓSn_{y}, oxide semiconductors, 2D materials, combinations thereof, or the like. For example, in some embodiments the first semiconductor materials and the third semiconductor materials include SiGe, and the second semiconductor materials include Si. In some embodiments, the first semiconductor materials and the third semiconductor materials have different concentrations of Ge, resulting in different etch selectivity and/or oxidation rates therebetween. In some embodiments, the semiconductor layers 924′A, 924′B, 926′U, and 926′L are formed by a deposition process, such as epitaxy. For example, epitaxial growth of the layers of the multilayer structure 922′ is performed by a molecular beam epitaxy (MBE) process, a metalorganic chemical vapor deposition (MOCVD) process, and/or other suitable epitaxial growth processes. The numbers of the semiconductor layers 926′L and 926′U may be 2 to about 101.

A plurality of semiconductor fins (e.g., semiconductor fins 928; alternatively referred to as active regions) are defined in the multilayer structure 922′ by one or more etching processes. In some embodiments, each semiconductor fin 928 corresponds to a pair of the lower active region and the upper active region vertically aligned along the Z direction. Each semiconductor fin 928 includes a substrate portion 920′ of the substrate 920, and a portion 934 of the multilayer structure 922′. The portion 934 of the multilayer structure 922′ is sometimes referred to as a stack of semiconductor layers 934. In some embodiments, the semiconductor fins 928 are fabricated using suitable processes, such as double-patterning or multi-patterning processes. For example, in one or more embodiments, a sacrificial layer is formed over a substrate and patterned using a photolithography process. Spacers are formed alongside the patterned sacrificial layer using a self-aligned process. The sacrificial layer is then removed, and the remaining spacers are then used to pattern the semiconductor fins 928 by etching the multilayer structure 922′ and the substrate 920. Example etch processes include, but are not limited to, dry etch, wet etch, reactive ion etch (RIE), and/or other suitable processes. In FIG. 11, two semiconductor fins 928 are illustrated; however, the number of the semiconductor fins 928 is not limited to two. In the present embodiments, the semiconductor fins 928 extend, or are elongated, along the X direction.

Isolation structures (e.g., isolation structures 932) may be formed over the substrate 920 and between the semiconductor fins 928. In some embodiments, the isolation structures 932 including an insulating material are formed over the substrate 920 and in trenches (not depicted) between the semiconductor fins 928. For example, the insulating material is deposited over the substrate 920 and the semiconductor fins 928. Example insulating materials of the isolation structures 932 include, but are not limited to, silicon oxide (SiO₂), fluorine-doped silicate glass (FSG), silicon nitride (SiN), silicon oxynitride (SiON), silicon oxycarbonitride (SiOCN), silicon carbonitride (SiCN), a low-k dielectric material, the like, or combinations thereof. The deposition of the insulating material includes a suitable method, such as low-pressure chemical vapor deposition (LPCVD), plasma enhanced CVD (PECVD) or flowable CVD (FCVD). Then, a planarization operation, such as a CMP process and/or an etch-back process, is performed such that the tops of the semiconductor fins 928 are exposed from the insulating material. A portion of the insulating materials between adjacent semiconductor fins 928 is removed. The remaining portion of the insulating materials configures the isolation structures 932. The partial removal of the insulating material includes dry etch, wet etch, or the like.

Subsequently, still referring to FIGS. 10 and 11, a dummy gate structure 942 including a dummy gate dielectric layer 936, a dummy gate electrode layer 938, and a mask structure 940 is formed over the semiconductor fins 928. In some embodiments, the dummy (or sacrificial) gate dielectric layer 936, the dummy (or sacrificial) gate electrode layer 938, and the mask structure 940 are deposited over the isolation structures 932 and semiconductor fins 928. In some embodiments, the dummy gate dielectric layer 936 includes one or more layers of dielectric material, such as SiO₂, SiN, a high-k dielectric material, the like, or combinations thereof. In some embodiments, the dummy gate dielectric layer 936 is deposited by a CVD process, a sub-atmospheric CVD (SACVD) process, a FCVD process, an atomic layer deposition (ALD) process, a physical vapor deposition (PVD) process, or other suitable process. In some embodiments, the dummy gate electrode layer 938 includes polycrystalline silicon (polysilicon). In some embodiments, the mask structure 940 includes a multilayer structure. In some embodiments, the dummy gate electrode layer 938 and the mask structure 940 are formed by one or more processes such as layer deposition, for example, CVD (including both LPCVD and PECVD), PVD, ALD, thermal oxidation, e-beam evaporation, or other suitable deposition techniques.

Referring to FIGS. 10 and 12, the dummy gate structures 942 are formed by one or more pattern and/or etch processes performed on the deposited dummy gate dielectric layer 936, the dummy gate electrode layer 938, and the mask structure 940. An example pattern process includes a lithography process. An example etch process includes dry etch (e.g., RIE), wet etch, other etch methods, and/or combinations thereof. Each dummy gate structure 942 includes a portion of each of the dummy gate dielectric layer 936, dummy gate electrode layer 938, and mask structure 940. The dummy gate structures 942 extend, or are elongated, along the Y direction. In FIG. 12, three dummy gate structures 942 are illustrated; however, the number of the dummy gate structures 942 is not limited to three.

Subsequently, corresponding gate spacers 944 are then formed over sidewalls of the dummy gate structure 942. For example, the gate spacers 944 are formed by first depositing a conformal layer that is subsequently etched back to form the gate spacers 944. The gate spacers 944 includes a dielectric material, such as SiO₂, SiN, silicon carbide, silicon oxycarbide, SiON, SiCN, SiOCN, the like, or combinations thereof. In some embodiments, the gate spacers 944 include multiple layers.

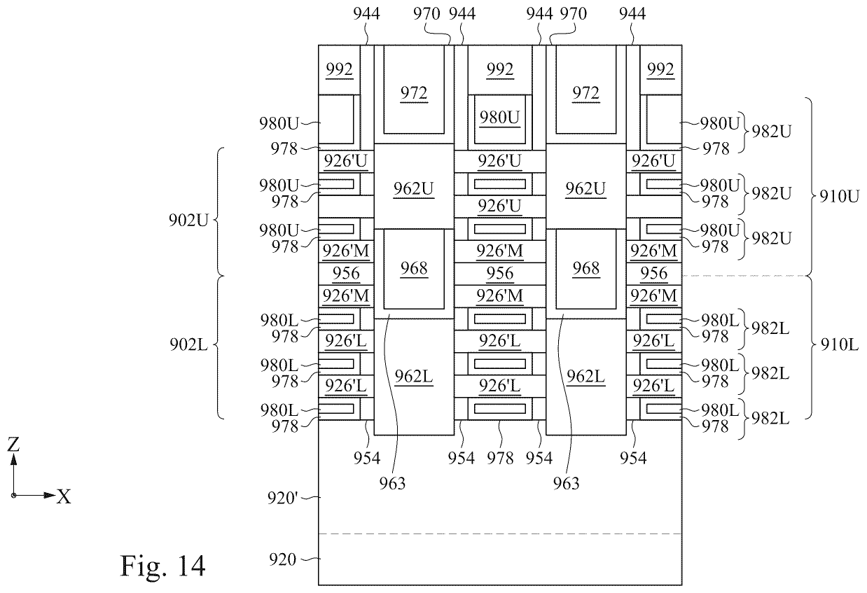

Referring to FIGS. 10 and 12, the semiconductor fins (or the multilayer structure) are etched to form source/drain recesses at operation S104. Specifically, source/drain recesses 946 are formed in each of the semiconductor fins 928. Exposed portions of the stack of semiconductor layers 934 of the semiconductor fins 928 not covered by the dummy gate structures 942 and the gat spacers 944 are selectively removed, e.g., by one or more suitable etch processes, such as dry etch, wet etch, or combinations thereof, to form the source/drain recesses 946. In FIG. 12, a lower most one of the second semiconductor layers 926′U and an uppermost one of the second semiconductor layers 926′L are designated as the middle second semiconductor layers 926′M which sandwich therebetween the middle first semiconductor layer 924′B. The middle second semiconductor layers 926′M and the middle first semiconductor layer 924′B are not configured to form channel regions of the upper transistor 910U and lower transistor 910L (see FIG. 14). Edge portions of the semiconductor layers 924′A, 924′B, 926′U, 926′L, and 926′M are exposed in the source/drain recesses 946. The source/drain recesses 946 also expose portions of the substrate portion 920′.

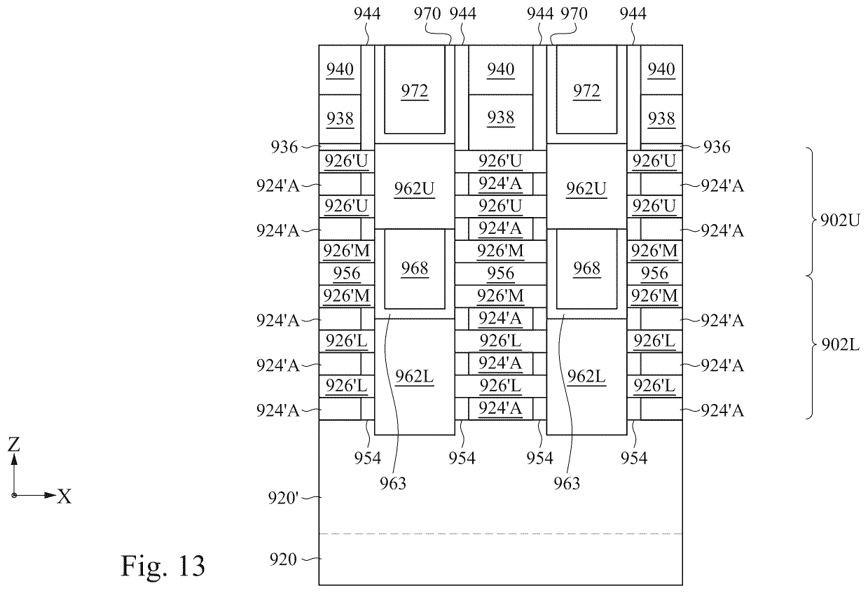

Referring to FIGS. 10 and 13, the second nanostructures and the fourth nanostructures are laterally recessed at operation S106, at one of the various stages of fabrication. As shown, respective end portions of each of the nanostructures 924′A (formed of Si₁₋ₓGeₓ) are removed (e.g., etched) using a “pull-back” process to pull each of the nanostructures 924′A back by a pull-back distance. For example, the pull-back process may include a hydrogen chloride (HCl) gas isotropic etching process, which etches SiGe with the lower Ge composition (e.g., Si₁₋ₓGeₓ) without attacking Si or SiGe with the higher Ge composition (e.g., Si_{1-y}Ge_{y}). As such, the nanostructures 926′L (Si), 926′M (Si), 926′U (Si), and 924′B (Si_{1-y}Ge_{y}) may remain substantially intact during this process, and a number of recesses, each inwardly extending from the source/drain recesses 946, can be formed.

Inner spacers are formed at operation S108. The inner spacers 954 can be formed by filling the recesses with a dielectric material. For example, the inner spacers 954 can be deposited using, e.g., a conformal deposition process and subsequent isotropic or anisotropic etch back to remove excess spacer material on the sidewalls of the stack. The dielectric material, used to form the inner spacer 954, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating gate sidewall spacers of transistors.

A fifth nanostructure of the multilayer structure is selectively removed at operation S110. After forming the inner spacers 954, the fifth nanostructure 924′B (see FIG. 12) can be selectively removed using an isotropic etching process that etches Si_{1-y}Ge_{y} without attacking Si. As such, the first nanostructures 926′L (Si) and third nanostructures 926′U (Si) can remain substantially intact, the fifth nanostructure 924′B (Si_{1-y}Ge_{y}) can be completely removed, and the remaining portions of the second nanostructures 924′A (Si₁₋ₓGeₓ) and fourth nanostructures 924′A (Si₁₋ₓGeₓ) can remain with the protection of the inner spacers 954.

Dielectric layer is formed between the lower portion and the upper portion at operation S112. After the fifth nanostructure 924′B is removed, a space is formed between the lower portion 902L and the upper portion 902U. Inner isolation structures 956 can be formed by filling the space with a dielectric material. The dielectric material, used to form the inner isolation structures 956, includes silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating structure for transistors.

Lower source/drain epitaxial structures are formed in the lower portion and upper source/drain epitaxial structures are formed in the upper portion at operation S114. As shown, a pair of lower source/drain epitaxial structures 962L are coupled to ends of each of the first nanostructures 926′L, respectively; and a pair of upper source/drain epitaxial structures 962U are coupled to ends of each of the third nanostructures 926′U, respectively. The lower source/drain epitaxial structures 962L can be formed through a first epitaxial growth process, followed by a second epitaxial growth process for forming the upper source/drain epitaxial structures 962U. Further, between the first epitaxial growth process and the second epitaxial growth process, one or more dielectric layers (e.g., CESL 963 and ILD layer 968) can be formed to electrically isolate the lower source/drain epitaxial structures 962L and the upper source/drain epitaxial structures 962U. Each of the first epitaxial growth process and the second epitaxial growth process can include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epitaxial processes. Specifically, the lower source/drain epitaxial structures 962L can be grown from the first nanostructures 926′L, and the upper source/drain epitaxial structures 962U can be grown from the third nanostructures 926′U.

The lower source/drain epitaxial structures 962L and the upper source/drain epitaxial structures 962U may each include silicon germanium (SiGe), indium arsenide (InAs), indium gallium arsenide (InGaAs), indium antimonide (InSb), germanium arsenide (GaAs), germanium antimonide (GaSb), indium aluminum phosphide (InAlP), indium phosphide (InP), any other suitable material, or combinations thereof. Further, in-situ doping (ISD) may be applied during the formation of each of the lower source/drain epitaxial structures 962L and the upper source/drain epitaxial structures 962U. For example, the lower source/drain epitaxial structures 962L can be doped by implanting p-type dopants, e.g., boron (B), etc., into them; and the upper source/drain epitaxial structures 962U can be doped by implanting n-type dopants, e.g., arsenic (As), phosphorous (P), etc., into them.

In some embodiments, a contact etch stop layer (CESL) 963 and an interlayer dielectric layer (ILD layer) 968 are formed over upper surfaces of the lower source/drain epitaxial structures 962L before forming the upper source/drain epitaxial structures 962U. The CESL 963 is formed at least over the upper surfaces of the lower source/drain epitaxy structures 962L, and exposed side faces of the middle second semiconductor layers 926′M and inner isolation structure 956. In some embodiments, the CESL 963 includes silicon nitride, silicon carbon nitride, silicon oxynitride, carbon nitride, silicon oxide, silicon carbon oxide, the like, or combinations thereof. In some example processes, the CESL 963 is formed by CVD, PECVD, ALD, or any suitable deposition technique.

The ILD layer 968 is formed over the CESL 963 and over the lower source/drain epitaxial structures 962L. In some embodiments, the ILD layer 968 includes the same material as the isolation structures 932 and/or is formed by the same method as the isolation structures 932. The CESL 963 and ILD layer 968 are removed outside the source/drain recesses 946, and partially removed inside the source/drain recesses 946, e.g., by a dry etch or wet etch. As a result, upper surfaces of the CESL 963 and ILD layer 968 are at a level of the lowermost semiconductor layer 924′A immediately above the upper middle semiconductor layer 926′M, as illustrated in FIG. 13. The CESL 963 and ILD layer 968 configure an isolation structure between the lower source/drain epitaxial structures 962L and the upper source/drain epitaxial structures 962U to be subsequently formed thereover.

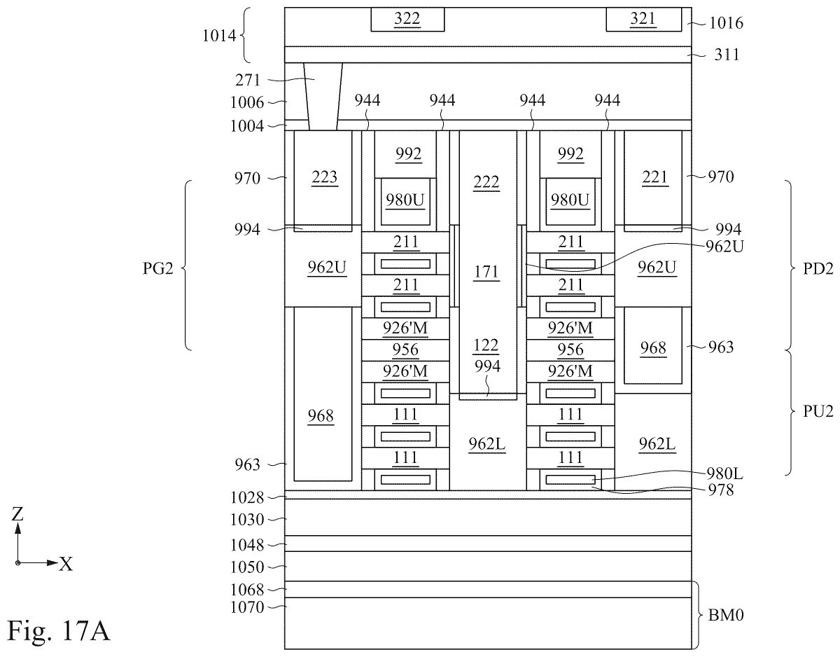

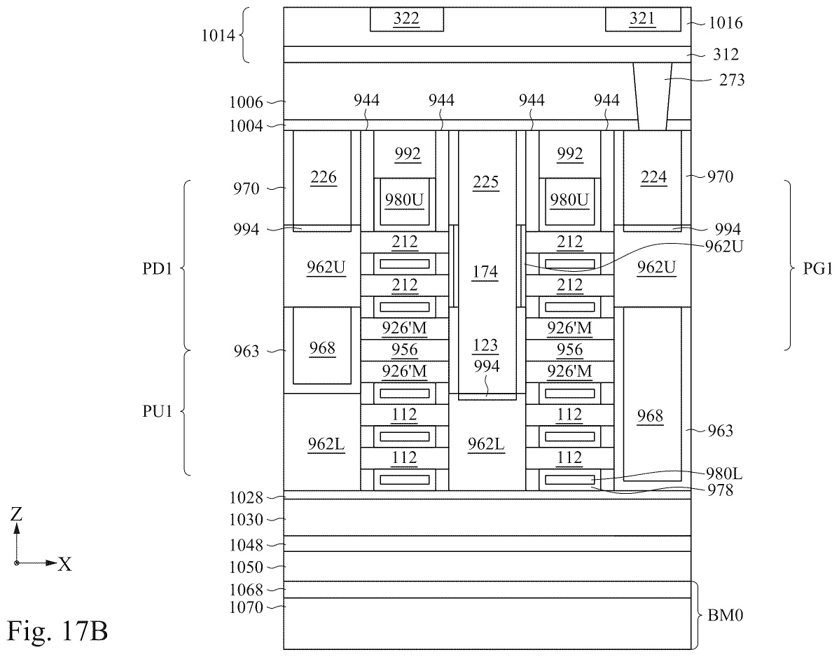

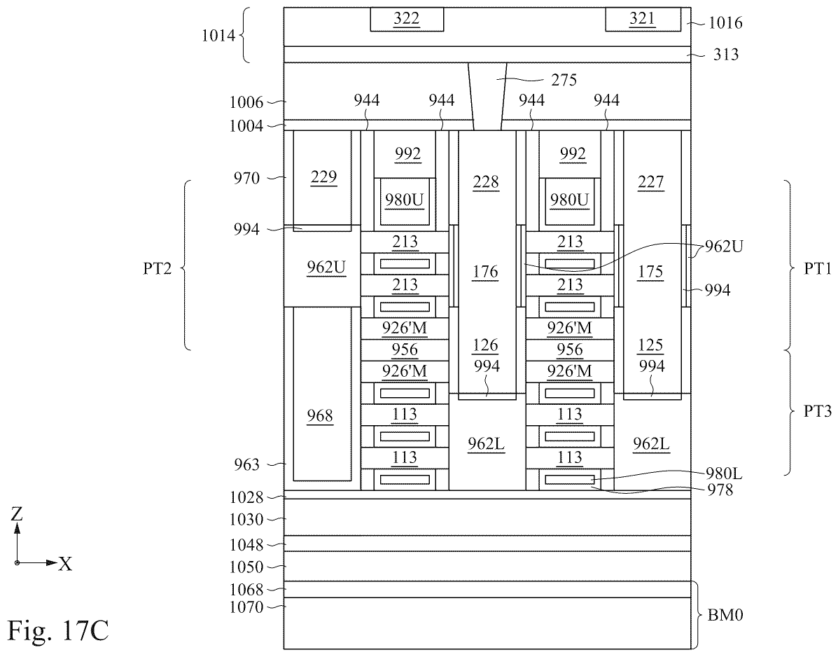

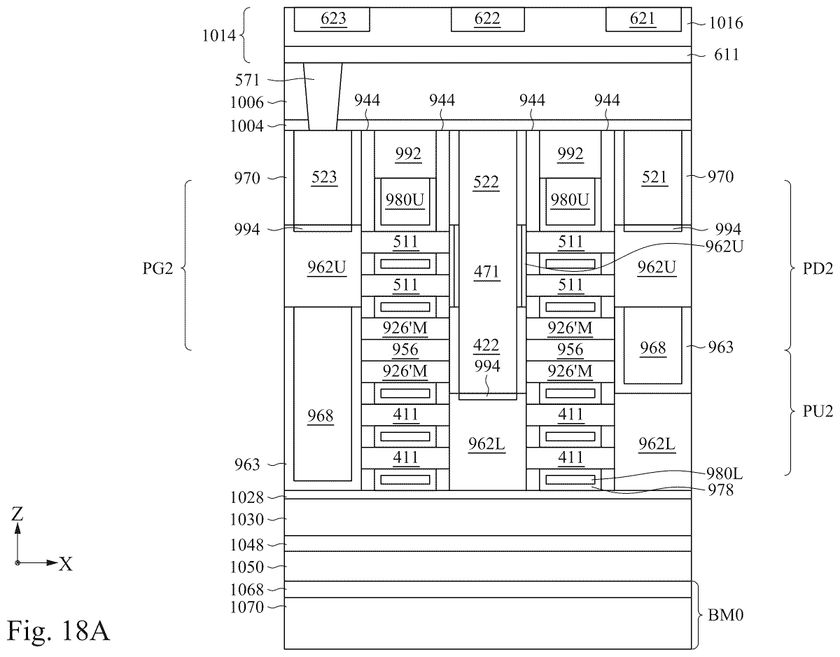

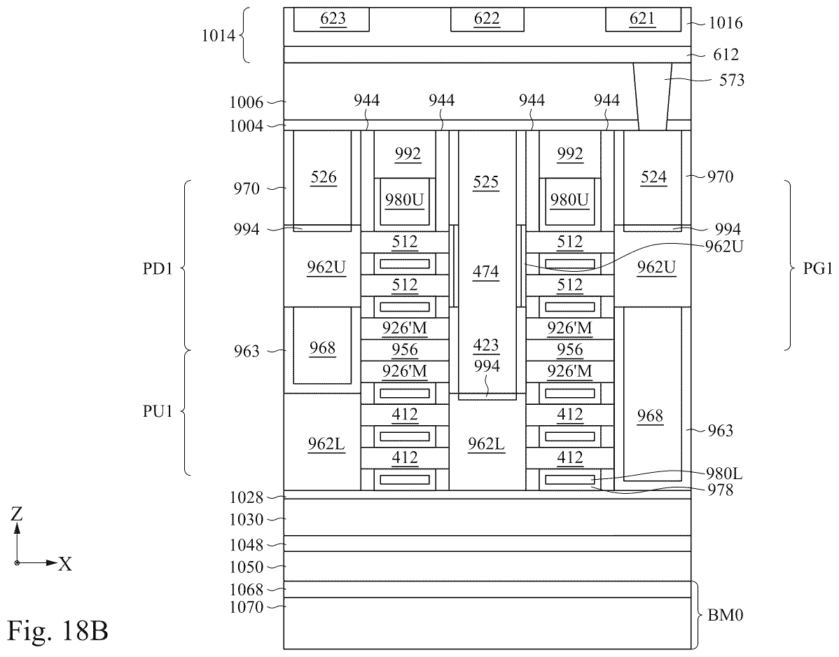

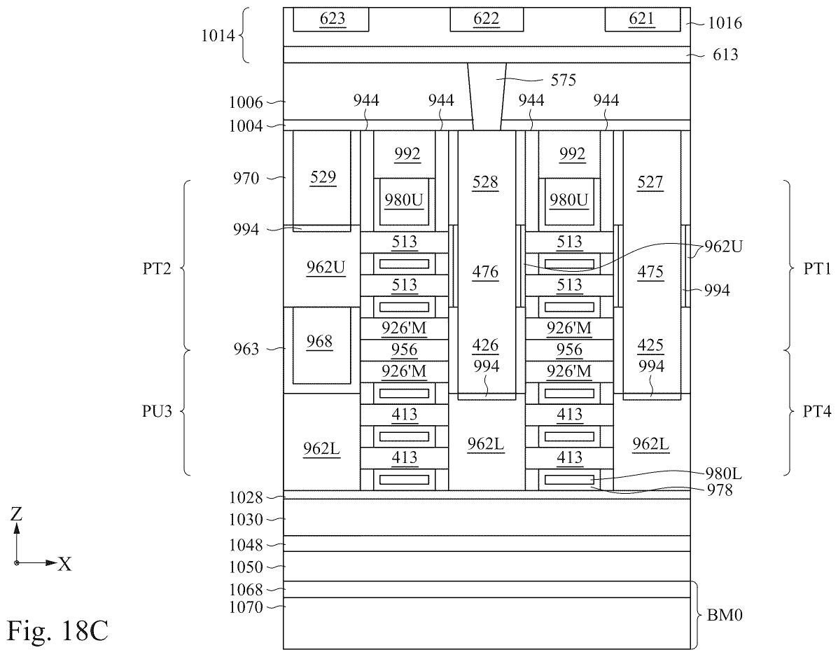

In some embodiments, after the formation of the lower source/drain epitaxial structures 962L, at least one of the lower source/drain epitaxial structures 962L is removed or etched to expose the end sidewalls of the semiconductor layers 924′A (see FIGS. 17A-18B), and the CESL 963 and the ILD layer 968 are filled in the lower portion 902L of the source/drain recess 946.

In some embodiments, a CESL 970 is formed over the upper source/drain epitaxial structures 962U and an ILD layer 972 is formed over the CESL 970. A chemical mechanical polishing (CMP) process is subsequently performed to planarize the CESL 970 and/or the ILD layer 972. Example materials of the CESL 970 include, but are not limited to, silicon nitride, silicon carbon nitride, silicon oxynitride, carbon nitride, silicon oxide, silicon carbon oxide, the like, or combinations thereof. The CESL 970 is formed by CVD, PECVD, ALD, or any suitable deposition technique. Example materials of the ILD layer 972 include, but are not limited to, tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 972 is deposited by a PECVD process or other suitable deposition technique.

Subsequently, referring to FIGS. 10 and 13-14, lower active gate structures are formed in the lower portion and upper active gate structures are formed in the upper portion at operation 116. Specifically, the dummy gate structure 942 and the remaining portions of the first semiconductor layers 924′A are replaced with metal gate structures (active gate structures) that each include a gate dielectric layer 978 and a gate electrode 980U/980L. A planarization process, such as a CMP process, is performed to remove the mask structure 940 and expose the dummy gate electrode layer 938. The planarization process also removes portions of the ILD layer 972 and the CESL 970. The exposed dummy gate electrode layer 938 and the dummy gate dielectric layer 936 are removed, e.g., by one or more suitable processes, such as dry etch, wet etch, or a combination thereof.

Next, the semiconductor layers 924′A are removed, e.g., by any suitable processes, such as dry etch, wet etch, or combinations thereof. The removal of the semiconductor layers 924′A exposes the inner spacers 954 and the semiconductor layers 926′U, 926′L, and creates spaces between and around exposed portions of the semiconductor layers 926′U, 926′L not covered by the inner spacers 954. The exposed portions of the semiconductor layers 926′U, 926′L configure the nanostructures 926′U, 926′L described with respect to FIG. 14. The middle second semiconductor layers 926′M and inner isolation structure 956 are covered by the CESL 963 and ILD layer 968 and are substantially unaffected by the removal of the semiconductor layers 924′A.

The gate dielectric layer 978 is formed over and around each of the nanostructures 926′U, 926′L. In some embodiments, the gate dielectric layer 978 includes the same material as the sacrificial gate dielectric layer 936. In some embodiments, the gate dielectric layer 978 includes a high-k dielectric material. In some embodiments, the gate dielectric layer 978 is formed by a conformal process, such as an ALD process.

The gate electrode 980U is formed over and around the gate dielectric layers 978, and the nanostructures 926′U, 926′L. The gate electrode 980U surrounds each of the nanostructures 926′U, i.e., is disposed above the inner isolation structure 956, and is configured to form each upper metal gate structure 982U. The gate electrode 980L surrounds each of the nanostructures 926′L, i.e., is disposed below the inner isolation structure 956, is configured to form each lower metal gate structure 982L. In some embodiments, the gate electrodes 980U and 980L each include, but are not limited to, polysilicon, Al, Cu, Ti, Ta, W, Co, Mo, nickel silicide, cobalt silicide, TaN, TiN, WN, WCN, TiAl, TiTaN, TiAlN, TaN, TaCN, TaC, TaSiN, metal alloys, the like, or combinations thereof. In some embodiments, the gate electrode material includes one or more work function metals. Example processes for depositing the gate electrode material include, but are not limited to, PVD, CVD, ALD, electro-plating, or other suitable methods.

In the depicted embodiments, the gate structures formed in the upper portion 902U of the memory device, i.e., above the inner isolation structure 956, are referred to as upper (metal or active) gate structures 982U that each include the gate electrode 980U, and the gate structures formed in the lower portion 902L of the device, i.e., below the inner isolation structure 956, are referred to as lower (metal or active) gate structures 982L that each include the gate electrode 980L. The formation of the gate electrodes 980U and gate electrodes 980L completes the formation of the upper transistors 910U and the lower transistors 910L in a front-end-of-line (FEOL) fabrication process. The lower transistors 910L are disposed in the first semiconductor level (i.e., the lower portion 902L), and the upper transistors 910U are disposed in the second semiconductor level (i.e., the upper portion 902U).

In some embodiments, the nanostructures 926′U, 926′L each has a thickness in a range of about 0.5 nm and about 50 nm, a width in a range of about 5 nm and about 100 nm, and/or a length in a range of about 5 nm and about 500 nm. A cross-sectional view of the nanostructures 926′U and 926′L may be square, rectangle, diamond, or other suitable shapes. A distance between the first semiconductor level and the second semiconductor level may be in a range of about 5 nm and about 100 nm. A thickness of the gate spacers 944 may be in a range of about 1 nm and about 25 nm.

In some embodiments, isolation structures to cut gate structures are formed. For example, portions of the dummy gate structure 942 or the gate structures 982L/982U are removed to form at least one recess therein, and an insulating material is filled in the recess to form the isolation structure. Therefore, the isolation structure is considered to be a structure that cuts the gate structure into two portions separated from each other.

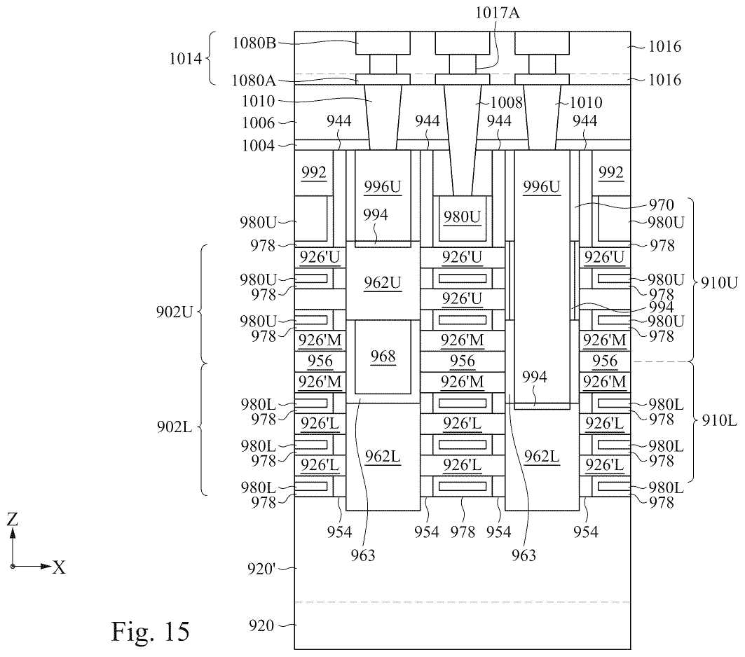

Referring to FIGS. 10 and 15, front-side connection structures are formed over the upper transistors at operation S118. Specifically, front-side contact structures are formed over and electrically coupled to the front-side of the memory device, including upper transistors 910U of the memory device in each memory cell. The front-side contact structures may include front-side source/drain contacts 996U electrically coupled to at least some of the upper source/drain epitaxial structures 962U in the upper portion 902U from the front-side of the substrate 920. One or some of the front-side source/drain contacts 996U further extends downward to the lower source/drain epitaxial structures 962L. The contact structures may further include front-side gate contacts 1008 electrically coupled to the upper metal gate structures 982U from the front-side of the substrate 920.

In some embodiments, forming the front-side source/drain contacts 996U includes patterning the ILD layer 972 to form trenches exposing the upper source/drain epitaxy structures 962U. A metal alloy layer 994 is formed over the exposed upper source/drain epitaxy structures 962U in the trench, and then the front-side source/drain contacts 996U are form in each trench and over the metal alloy layer 994. The conductive material of the front-side source/drain contacts 996U may be deposited by any suitable process, such as PVD, ECP, or CVD, and planarized by a CMP process, for example.

Forming the front-side gate contacts 1008 may include forming a mask structure 992 over the upper metal gate structures 982U, a CESL 1004 over the mask structure 992, and an ILD layer 1006 over the CESL 1004. Compositions of the mask structure 992, the ILD layer 1006 and the CESL 1004 may be analogous to those of the mask structure 940, the ILD layer 972 and the CESL 970, respectively. The stack of the mask structure 992, the ILD layer 1006, and the CESL 1004 is then patterned to form trenches in which the front-side gate contacts 1008 are formed by a series of deposition and planarization techniques described above with respect to forming the front-side source/drain contacts 996U.

In some embodiments, after the formation of the transistors 910L and 910U, one or more connection structures (e.g., the connection structures 151-153, 251-255, 451-453, and 551-555 as mentioned above) may be formed in the first semiconductor level and the second semiconductor level. For example, the dielectric structures (e.g., the CESLs 963 and 970 and the ILD layers 968 and 972 may be etched to form trenches therein, and conductive materials are filled in the trenches to form the connection structures.

Front-side interconnect structures and metallization layers are formed over and electrically coupled to the front-side contact structures of the memory device. Forming front-side conductive vias 1010 may include patterning the ILD layer 1006 and the CESL 1004 to form via openings, and then filling the via openings with a conductive material described above. The conductive material may subsequently be planarized using a CMP process, resulting in the front-side conductive vias 1010.

A multilayer interconnect (MLI) structure 1014 is formed over and electrically coupled to the front-side gate contacts 1008 and the front-side source/drain contacts 996U, for example. The MLI structure 1014 includes a plurality of front-side conductive lines 1018A and 1018B, and front-side via contacts 1017A sequentially and alternately formed over the front-side gate contacts 1008 and the front-side conductive vias 1010. In some embodiments, the front-side conductive lines 1018A are formed in the metallization layer M1, the front-side conductive lines 1018B immediately over the front-side conductive lines 1018A are formed in the metallization layer M2, and so on. The MLI structure 1014 further includes various ILD layers 1016 in which the metal lines and the conductive vias are embedded. Although not depicted herein, additional dielectric layers, front-side conductive vias, and front-side conductive lines may be formed over the front-side conductive lines 1018B as a part of the MLI structure 1014. Example conductive materials of the front-side connection structures include Cu, W, WN, Mo, Co, Ru, RuO, Al, Ti, Ta, TiN, TaN, Pt, Ni, Ag, Au, the like, or combinations (or alloys) thereof.

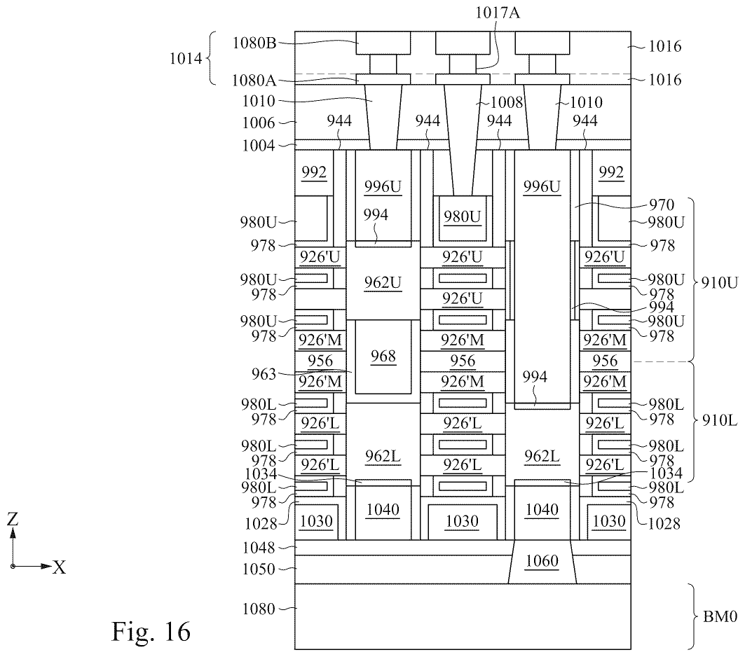

Referring to FIGS. 10 and 16, backside connection structures are formed under the lower transistors at operation S120. For example, the substrate 920 is flipped to expose the backside of the substrate 920 in preparation for fabricating the backside components of the memory device. The flipped substrate 920 may be polished using a CMP process, for example, to remove excess portions of the substrate 920 and expose a backside of the lower transistors 910L.

Backside contact structures, interconnect structures, and metallization layers analogous to those on the front-side of the memory device are formed over and electrically coupled to the backside of the lower transistors 910L in each memory cell. The backside contact structures, interconnect structures, and metallization layers may be formed in processes similar to those of the corresponding front-side features and are thus only briefly described below.

Dielectric layers 1028 and 1030 are formed on the backside of the lower transistor 910L. The dielectric layers 1028 and 1030 are patterned to form trenches in which metal alloy layers 1034 and backside source/drain contacts 1040 over the metal alloy layers 1034 are formed. In this regard, the backside source/drain contacts 1040 are electrically coupled to the backside of the lower source/drain epitaxy structures 962L. Subsequently, dielectric layers 1048 and 1050, analogous to the dielectric layers 1028 and 1030, respectively, are formed over the backside source/drain contacts 1040. The dielectric layers 1048 and 1050 are patterned to form trenches in which backside conductive vias 1060 are formed and electrically coupled to the respective backside source/drain contacts 1040. Thereafter, dielectric layers 1068 and 1070 (see FIGS. 17A-18C), analogous to the dielectric layers 1028 and 1030, respectively, are formed over the backside conductive vias 1060. The dielectric layers 1068 and 1070 are then patterned to form trenches in which backside conductive lines 1080 are formed as portions of a backside metallization layer BM0. Although not depicted herein, additional dielectric layers, backside via contacts, and backside metal lines may be formed over the backside conductive lines 1080. Example conductive materials of the backside connection structures include Cu, W, WN, Mo, Co, Ru, RuO, Al, Ti, Ta, TiN, TaN, Pt, Ni, Ag, Au, the like, or combinations (or alloys) thereof.

Although the structures and methods will be discussed in terms of CFET structures devices, one of ordinary skill in the art would understand that the structures and methods are not so limited and certain aspects of the embodiments discussed are suitable for inclusion in manufacturing processes for other classes and configurations of IC devices. The structures and methods disclosed herein are equally applicable to various manufacturing processes used in achieving the vertical stack structures including both monolithic CFET manufacturing processes and sequential CFET manufacturing processes.

FIG. 17A is a cross-sectional view of the memory device 10A along a line I-I in FIGS. 3A-3C, in accordance with some embodiments of the present disclosure, FIG. 17B is a cross-sectional view of the memory device 10A along a line II-II in FIGS. 3A-3C, in accordance with some embodiments of the present disclosure, and FIG. 17C is a cross-sectional view of the memory device 10A along a line III-III in FIGS. 3A-3C, in accordance with some embodiments of the present disclosure. In some embodiments, the active regions 111-113 and 211-213 may be nanostructures 926′L, 926′U (see FIG. 16). As shown in FIG. 17A, the lower source/drain epitaxial structures 962L below the transistor PG2 is removed, and dielectric structure (e.g., the CESL 963 and the ILD layer 968) is filled in the source/drain recess, such that the dielectric structure is in contact with sidewalls of the active regions 111. Also, in FIG. 17B, the lower source/drain epitaxial structures 962L below the transistor PG1 is removed, and dielectric structure (e.g., the CESL 963 and the ILD layer 968) is filled in the source/drain recess, such that the dielectric structure is in contact with sidewalls of the active regions 112. Similarly, in FIG. 17C, the lower source/drain epitaxial structures 962L below the transistor PT2 is removed, and dielectric structure (e.g., the CESL 963 and the ILD layer 968) is filled in the source/drain recess, such that the dielectric structure is in contact with sidewalls of the active regions 113. Further, the source/drain structures 121-126 and 221-229 may be referred to as the source/drain contacts 996U in FIG. 16. The transistors PD2 and PU2 form a complementary field effect transistor (CFET), the transistors PD1 and PU1 form a CFET, and the transistors PT1 and PT3 form a CFET.

FIG. 18A is a cross-sectional view of the memory device 10B along a line IV-IV in FIGS. 8A-8C, in accordance with some embodiments of the present disclosure, FIG. 18B is a cross-sectional view of the memory device 10B along a line V-V in FIGS. 8A-8C, in accordance with some embodiments of the present disclosure, and FIG. 18C is a cross-sectional view of the memory device 10B along a line VI-VI in FIGS. 8A-8C, in accordance with some embodiments of the present disclosure. In some embodiments, the active regions 411-413 and 511-513 may be nanostructures 926′L, 926′U (see FIG. 16) and the source/drain epitaxial structures 962L, 962U. As shown in FIG. 18A, the lower source/drain epitaxial structures 962L below the transistor PG2 is removed, and dielectric structure (e.g., the CESL 963 and the ILD layer 968) is filled in the source/drain recess, such that the dielectric structure is in contact with sidewalls of the active regions 411. Also, in FIG. 18B, the lower source/drain epitaxial structures 962L below the transistor PG1 is removed, and dielectric structure (e.g., the CESL 963 and the ILD layer 968) is filled in the source/drain recess, such that the dielectric structure is in contact with sidewalls of the active regions 412. Further, the source/drain structures 421-427 and 521-529 may be referred to as the source/drain contacts 996U in FIG. 16. The transistors PD2 and PU2 form a CFET, the transistors PD1 and PU1 form a CFET, the transistors PT1 and PT4 form a CFET, and the transistors PT2 and PT3 form a CFET.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the additional pass transistor improves the output signal degradation issue while not increasing the layout area of the 9T memory device. Also, the additional pass transistor allows higher input voltages in the logic circuit, such that the 9T memory device has an ability to do high speed computing without losing result signals. In 10T memory device, the additional pass transistors are able to compute dual DCIM applications without increasing the layout area of the memory device.

According to some embodiments, a device includes a first transistor, a second transistor, a third transistor, and a fourth transistor. The first transistor and the second transistor are disposed in a first semiconductor level. The first transistor includes a first active region extending in a first direction, and the first transistor and the second transistor are arranged in a second direction different from the first direction. The third transistor is disposed in the first semiconductor level, between the first transistor and the second transistor, and is misaligned with the first transistor in the second direction. The third transistor is electrically connected to the first transistor and the second transistor. The fourth transistor is disposed in a second semiconductor level and over the first transistor to form a complementary field effect transistor with the first transistor. The second semiconductor level is over the first semiconductor level.

According to some embodiments, a device includes a first transistor, a second transistor, a third transistor, a fourth transistor, and a fifth transistor. The first transistor, the second transistor, and the third transistor are disposed in a first semiconductor level. A source/drain structure of the first transistor is electrically connected to a gate structure of the second transistor and a gate structure of the third transistor, an active region of the first transistor extends in a first direction, and the gate structure of the second transistor extends in a second direction different from the first direction. The fourth transistor is disposed in a second semiconductor level and over the first transistor. The active region of the first transistor is aligned with an active region of the fourth transistor in a third direction different from the first direction and the second direction. The fifth transistor is disposed in a second semiconductor level, wherein the fourth transistor and the fifth transistor share a same source/drain structure.

According to some embodiments, a method includes forming a first active region, a second active region, a third active region, and a fourth active region. The first to third active regions are in a first semiconductor level, extend in a first direction, and are arranged in a second direction different from the first direction. The fourth active region is in a second semiconductor level and aligned with the first active region in a third direction different from the first direction and the second direction. A first gate structure is formed to cover the first active region and the fourth active region. A second gate structure is formed to cover the second active region. A third gate structure is formed to cover the third active region. The first gate structure is aligned with the third gate structure in the second direction. Lower source/drain epitaxial structures are formed over the first to fourth active regions. One of the lower source/drain epitaxial structures between the lower source/drain epitaxial structure over the first active region and the lower source/drain epitaxial structure over the third active region is removed. Upper source/drain epitaxial structures are formed over the fourth active region. Front-side connection structures are formed over the second semiconductor level and connected to at least one of the upper source/drain epitaxial structures and the lower source/drain epitaxial structures. Backside connection structures are formed under the first semiconductor level and connected to at least one of the upper source/drain epitaxial structures and the lower source/drain epitaxial structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a first transistor and a second transistor disposed in a first semiconductor level, wherein the first transistor comprises a first active region extending in a first direction, and the first transistor and the second transistor are arranged in a second direction different from the first direction;
a third transistor disposed in the first semiconductor level, between the first transistor and the second transistor, and misaligned with the first transistor in the second direction, wherein the third transistor is electrically connected to the first transistor and the second transistor; and
a fourth transistor disposed in a second semiconductor level and over the first transistor to form a complementary field effect transistor with the first transistor, wherein the second semiconductor level is over the first semiconductor level.

2. The device of claim 1, wherein a source/drain structure of the first transistor is electrically connected to a source/drain structure of the fourth transistor.

3. The device of claim 1, further comprising a fifth transistor disposed in the first semiconductor level, wherein the fifth transistor is aligned with the third transistor in the second direction and aligned with the second transistor in the first direction, and the fifth transistor is electrically connected to the third transistor.

4. The device of claim 3, wherein the fifth transistor and the second transistor share a same source/drain structure.

5. The device of claim 4, wherein the source/drain structure of the fifth transistor is aligned with a source/drain structure of the third transistor in the second direction.

6. The device of claim 3, wherein a gate structure of the third transistor is electrically connected to a gate structure of the fifth transistor.

7. The device of claim 1, wherein a gate structure of the first transistor is electrically isolated from a gate structure of the second transistor.

8. The device of claim 1, further comprising a first conductive line and a second conductive line under the first semiconductor level, wherein the first conductive line and the second conductive line extend in the first direction.

9. The device of claim 8, wherein the first active region is between the first conductive line and the second conductive line in a top view.

10. The device of claim 8, wherein the fourth transistor is electrically connected to the first conductive line, and the first transistor is electrically connected to the second conductive line.

11. A device comprising:
a first transistor, a second transistor, and a third transistor disposed in a first semiconductor level, wherein a source/drain structure of the first transistor is electrically connected to a gate structure of the second transistor and a gate structure of the third transistor, an active region of the first transistor extends in a first direction, and the gate structure of the second transistor extends in a second direction different from the first direction;
a fourth transistor disposed in a second semiconductor level and over the first transistor, wherein the active region of the first transistor is aligned with an active region of the fourth transistor in a third direction different from the first direction and the second direction; and
a fifth transistor disposed in a second semiconductor level, wherein the fourth transistor and the fifth transistor share a same source/drain structure.

12. The device of claim 11, wherein the fifth transistor is not directly over the first transistor, the second transistor, and the third transistor.

13. The device of claim 11, wherein the third transistor is aligned with the first transistor in the second direction.

14. The device of claim 11, wherein the third transistor is aligned with the second transistor in the second direction.

15. The device of claim 11, wherein the first transistor, the second transistor, and the third transistor have the same electrical conductivity type.

16. The device of claim 11, further comprising a sixth transistor disposed in the first semiconductor level and aligned with the third transistor in the first direction.

17. The device of claim 16, wherein a gate structure of the sixth transistor is electrically connected to a source/drain structure of the second transistor.

18. The device of claim 11, further comprising a sixth transistor disposed in the second semiconductor level and aligned with the third transistor in the third direction, wherein a source/drain structure of the third transistor is electrically connected to a source/drain structure of the sixth transistor.

19. A method comprising:
forming a first active region, a second active region, a third active region, and a fourth active region, wherein the first to third active regions are in a first semiconductor level, extending in a first direction, and arranged in a second direction different from the first direction, and the fourth active region is in a second semiconductor level and aligned with the first active region in a third direction different from the first direction and the second direction;
forming a first gate structure to cover the first active region and the fourth active region;
forming a second gate structure to cover the second active region;
forming a third gate structure to cover the third active region, wherein the first gate structure is aligned with the third gate structure in the second direction;
forming lower source/drain epitaxial structures over the first to fourth active regions;
removing one of the lower source/drain epitaxial structures between the lower source/drain epitaxial structure over the first active region and the lower source/drain epitaxial structure over the third active region;
forming upper source/drain epitaxial structures over the fourth active region;
forming front-side connection structures over the second semiconductor level and connected to at least one of the upper source/drain epitaxial structures and the lower source/drain epitaxial structures; and
forming backside connection structures under the first semiconductor level and connected to at least one of the upper source/drain epitaxial structures and the lower source/drain epitaxial structures.

20. The method of claim 19, wherein after removing the lower source/drain epitaxial structures, depositing a dielectric structure to cover a sidewall of the second active region.
